(19) United States
(12) Patent Application Publication
(10) Pub. No.: US 2026/0198043 A1
(43) Pub. Date: Jul. 9, 2026

(54) SEMICONDUCTOR DEVICE

(71) Applicant: SAMSUNG ELECTRONICS CO., LTD., Suwon-si (KR)

(72) Inventors: Seungmin Song, Suwon-si (KR); Junggil Yang, Suwon-si (KR); Hyungsuk Lee, Suwon-si (KR)

(73) Assignee: SAMSUNG ELECTRONICS CO., LTD., Suwon-si (KR)

(21) Appl. No.: 19/272,460

(22) Filed: Jul. 17, 2025

(30) Foreign Application Priority Data
Jan. 7, 2025 (KR) 10-2025-0002107

(51) Int. Cl. H10D 30/00; H01L 23/522; H01L 23/528; H10D 30/01; H10D 30/43; H10D 62/10; H10D 62/13; H10D 62/60; H10D 62/832; H10D 64/23; H10D 64/27; H10D 86/00; H10D 86/01

(52) U.S. Cl. CPC H10D 30/503; H10D 30/43; H10D 30/506; H10D 62/102; H10D 62/121; H10D 62/151; H10D 62/60; H10D 62/832; H10D 64/256; H10D 64/516; H10D 64/518; H10D 86/00; H10W 20/43; H10W 20/435; H10W 20/498; H10D 30/014; H10D 30/0191; H10D 86/01

(57) ABSTRACT

A semiconductor device may include: a substrate; an active pattern on the substrate; a source/drain pattern on the active pattern; a channel pattern connected to the source/drain pattern, the channel pattern including semiconductor patterns that are spaced apart from each other; and a gate electrode extending in a first direction such as to cross the channel pattern, wherein the semiconductor patterns include a first semiconductor pattern, a second semiconductor pattern on the first semiconductor pattern, and a third semiconductor pattern on the second semiconductor pattern, wherein the gate electrode includes: a first inner part between the active pattern and the first semiconductor pattern; a second inner part between the first semiconductor pattern and the second semiconductor pattern; and a third inner part between the second semiconductor pattern and the third semiconductor pattern, and wherein a width of the first inner part is a smaller than a width of the second inner part and a width of the third inner part.

### CROSS-REFERENCE TO RELATED APPLICATION

This U.S. non-provisional patent application claims priority under 35 U.S.C. § 119 to Korean Patent Application No. 10-2025-0002107, filed on Jan. 7, 2025, the disclosure of which is hereby incorporated by reference in its entirety.

### BACKGROUND

### 1. Field

Some embodiments of the present disclosure relate to a semiconductor device and a method for manufacturing the same, and more particularly, to a semiconductor device including a field effect transistor and a method for manufacturing the same.

### 2. Description of Background Art

A semiconductor device may include an integrated circuit composed of metal-oxide-semiconductor field effect transistors (MOSFETs). As a size and a design rule of the semiconductor device are gradually decreasing, scaling down of the metal-oxide-semiconductor field effect transistors is also gradually being accelerated. As the metal-oxide-semiconductor field effect transistors are gradually scaled down, operation characteristics of the semiconductor device may be deteriorated. Accordingly, research on various methods for overcoming limitation caused by high-integration of the semiconductor device and forming the semiconductor device with more excellent performance is being conducted.

### SUMMARY

According to some embodiments of the present disclosure, a semiconductor device with improved reliability may be provided.

According to some embodiments of the present disclosure, a semiconductor device with improved electrical characteristics may be provided.

According to some embodiments of the present disclosure, a semiconductor device may include: a substrate; an active pattern on the substrate; a source/drain pattern on the active pattern; a channel pattern connected to the source/drain pattern, the channel pattern including semiconductor patterns that are spaced apart from each other; and a gate electrode extending in a first direction such as to cross the channel pattern, wherein the semiconductor patterns include a first semiconductor pattern, a second semiconductor pattern on the first semiconductor pattern, and a third semiconductor pattern on the second semiconductor pattern, wherein the gate electrode includes: a first inner part between the active pattern and the first semiconductor pattern; a second inner part between the first semiconductor pattern and the second semiconductor pattern; and a third inner part between the second semiconductor pattern and the third semiconductor pattern, and wherein a width of the first inner part is a smaller than a width of the second inner part and a width of the third inner part.

According to some embodiments of the present disclosure, a semiconductor device may include: a substrate; an active pattern on the substrate; a source/drain pattern on the active pattern; a channel pattern connected to the source/drain pattern, the channel pattern including semiconductor patterns spaced apart from each other, wherein the semiconductor patterns includes a first semiconductor pattern that is a lowermost semiconductor pattern among the semiconductor patterns; a gate electrode extending in a first direction such as to cross the channel pattern; and an inner spacer between the substrate and the first semiconductor pattern, wherein the source/drain pattern includes: a first part in contact with the inner spacer; and a second part in contact with one of the semiconductor patterns other than the first semiconductor pattern, and wherein the first part has a higher germanium (Ge) concentration than a (Ge) concentration of the second part.

According to some embodiments of the present disclosure, a semiconductor device may include: an insulating substrate; a channel pattern on the insulating substrate, the channel pattern including a first semiconductor pattern, a second semiconductor pattern on the first semiconductor pattern, and a third semiconductor pattern on the second semiconductor pattern, wherein the first semiconductor pattern, the second semiconductor pattern, and the third semiconductor pattern are spaced apart from each other; a source/drain pattern connected to the channel pattern; a gate electrode extending in a first direction such as to cross the channel pattern, the gate electrode including: a first inner part between the insulating substrate and the first semiconductor pattern; a second inner part between the first semiconductor pattern and the second semiconductor pattern; a third inner part between the second semiconductor pattern and the third semiconductor pattern; and an outer part on the third semiconductor pattern; a gate insulating layer between the gate electrode and the channel pattern; a gate spacer on a sidewall of the gate electrode; a gate capping pattern on an upper surface of the gate electrode; an interlayered insulating layer on the source/drain pattern and the gate capping pattern; a gate contact penetrating the interlayered insulating layer and the gate capping pattern, the gate contact electrically connected to the gate electrode; a first metal layer on the interlayered insulating layer, and the first metal layer including a first wire electrically connected to the gate contact; a lower power wire in a lower portion of the insulating substrate; a power transmission network layer under the insulating substrate; and a backside contact penetrating the insulating substrate, the backside contact electrically connected the lower power wire and the source/drain pattern, wherein a width of the first inner part is the same as or a smaller than a width of the outer part, and wherein a minimum width of the second inner part and a minimum width of the third inner part are greater than a width of the outer part.

According to some embodiments of the present disclosures, a method for manufacturing a semiconductor device may include alternately stacking first semiconductor layers and second semiconductor layers on a substrate, forming a first recess by etching the first semiconductor layers and the second semiconductor layers, and forming an inner spacer and a first source/drain pattern in the first recess, wherein the second semiconductor layers include a first sacrificial layer that is a lowermost semiconductor layer among the second semiconductor layers, the first sacrificial layer includes a material having etching selectivity with respect to other semiconductor layers among the second semiconductor layers, and the forming of the inner spacer includes forming a first indent region by indenting the first sacrificial layer by performing an etching process in the first recess, and filling the first indent region with an insulating material.

### BRIEF DESCRIPTION OF DRAWINGS

The accompanying drawings are included to provide a further understanding of the present disclosure, and are incorporated in and constitute a part of this specification. The drawings illustrate non-limiting example embodiments of the present disclosure and, together with the description, serve to explain example aspects of the present disclosure. In the drawings:

FIGS. 1 to 3 are conceptual diagrams for describing logic cells of a semiconductor device according to embodiments of the present disclosure;

FIG. 4 is a plan view for describing a semiconductor device according to embodiments of the present disclosure;

FIG. 5A is a cross-sectional view taken along a line A-A′ of FIG. 4;

FIG. 5B is a cross-sectional view taken along a line B-B′ of FIG. 4;

FIG. 5C is a cross-sectional view taken along a line C-C′ of FIG. 4;

FIG. 5D is a cross-sectional view taken along a line D-D′ of FIG. 4;

FIG. 5E is a cross-sectional view taken along a line E-E′ of FIG. 4;

FIG. 6 is an enlarged diagram illustrating an embodiment of a region of FIG. 5A;

FIG. 7 is an enlarged diagram illustrating an embodiment of the region of FIG. 5A;

FIGS. 8A to 16B are cross-sectional views for describing a method for manufacturing a semiconductor device according to embodiments of the present disclosure;

FIGS. 17A to 17E are enlarged diagrams for describing a method for manufacturing a semiconductor device according to an embodiment shown in FIG. 6; and

FIGS. 18A to 18C are enlarged diagrams for describing a method for manufacturing a semiconductor device according to an embodiment shown in FIG. 7.

### DETAILED DESCRIPTION

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

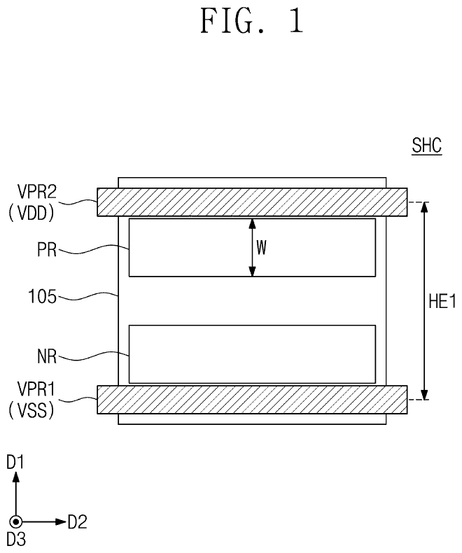

FIGS. 1 to 3 are conceptual diagrams for describing logic cells of a semiconductor device according to embodiments of the present disclosure.

Referring to FIG. 1, a single height cell SHC may be provided. Specifically, a first power wire VPR1 and a second power wire VPR2 may be provided on a substrate 105. The first power wire VPR1 may be a path through which a source voltage VSS, for example, a ground voltage is provided. The second power wire VPR2 may be a path through which a drain voltage VDD, for example, a power voltage is provided.

The single height cell SHC may be defined by and between the first lower power wire VPR1 and the second lower power wire VPR2. The single height cell SHC may include one PMOSFET region PR and one NMOSFET region NR. In other words, the single height cell SHC may have a structure in which a CMOS is provided between the first lower power wire VPR1 and the second lower power wire VPR2.

The PMOSFET region PR and the NMOSFET region NR may each have a width W in a first direction D1. A length of the single height cell SHC in the first direction D1 may be defined as a first height HE1. The first height HE1 may be substantially the same as a distance (e.g., a pitch) between the first lower power wire VPR1 and the second lower power wire VPR2.

The single height cell SHC may constitute one logic cell. In the present specification, the logic cell may mean a logic device (e.g., AND, OR, XOR, XNOR, an inverter, or the like) that performs a specific function. That is, the logic cell may include transistors for constituting the logic device, and wires connecting the transistors to each other.

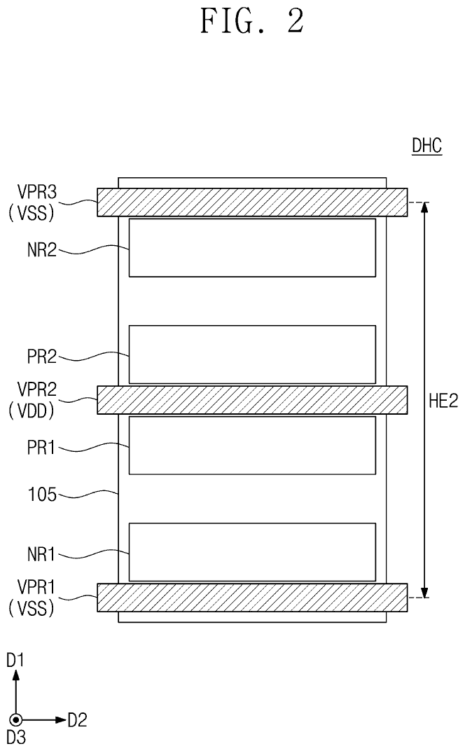

Referring to FIG. 2, a double height cell DHC may be provided. Specifically, the first lower power wire VPR1, the second lower power wire VPR2, and a third lower power wire VPR3 may be provided on the substrate 105. The second lower power wire VPR2 may be disposed between the first lower power wire VPR1 and the third lower power wire VPR3. The third lower power wire VPR3 may be a path through which the source voltage VSS is provided.

The double height cell DHC may be defined by and between the first lower power wire VPR1 and the third lower power wire VPR3. The double height cell DHC may include a first PMOSFET region PR1, a second PMOSFET region PR2, a first NMOSFET region NR1, and a second NMOSFET region NR2.

The first NMOSFET region NR1 may be adjacent to the first lower power wire VPR1. The second NMOSFET region NR2 may be adjacent to the third lower power wire VPR3. The first PMOSFET region PR1 and the second PMOSFET region PR2 may be adjacent to the second lower power wire VPR2. In a plan view, the second lower power wire VPR2 may be disposed between the first PMOSFET region PR1 and the second PMOSFET region PR2.

A length of the double height cell DHC in the first direction D1 may be defined as a second height HE2. The second height HE2 may be about twice larger than the first height HE1 of FIG. 1. The first PMOSFET region PR1 and the second PMOSFET region PR2 of the double height cell DHC may operate together as one PMOSFET region. Accordingly, a channel size of a PMOS transistor of the double height cell DHC may be greater than a channel size of the PMOS transistor of the single height cell SHC of FIG. 1 above.

For example, the channel size of the PMOS transistor of the double height cell DHC may be about twice larger than the channel size of the PMOS transistor of the single height cell SHC. As a result, the double height cell DHC may operate faster than the single height cell SHC. According to the present disclosure, the double height cell DHC illustrated in FIG. 2 may be defined as a multi-height cell. According to some embodiments, the multi-height cell may include a triple height cell of which a cell height is about three times larger than the cell height of the single height cell SHC.

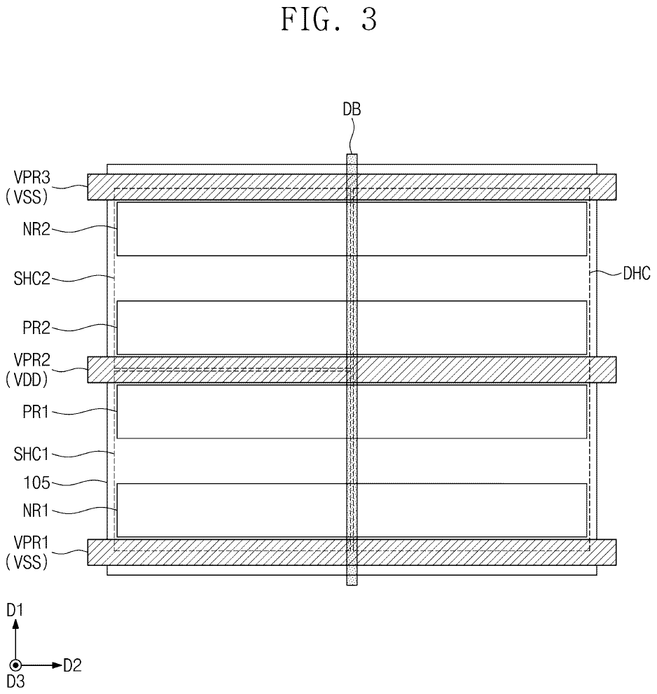

Referring to FIG. 3, a first single height cell SHC1, a second single height cell SHC2, and the double height cell DHC may be two-dimensionally disposed on the substrate 105. The first single height cell SHC1 may be disposed between the first lower power wire VPR1 and the second lower power wire VPR2. The second single height cell SHC2 may be disposed between the second lower power wire VPR2 and the third lower power wire VPR3. The second single height cell SHC2 may be adjacent to the first single height cell SHC1 in the first direction D1.

The double height cell DHC may be disposed between the first lower power wire VPR1 and the third lower power wire VPR3. The double height cell DHC may be adjacent to the first single height cell SHC1 and the second single height cell SHC2 in a second direction D2 that crosses (e.g., is perpendicular to) the first direction D1.

A separation structure DB may be provided between the first single height cell SHC1 and the double height cell DHC, and between the second single height cell SHC2 and the double height cell DHC. An active region of the double height cell DHC may be electrically separated from an active region of each of the first single height cell SHC1 and the second single height cell SHC2 by the separation structure DB.

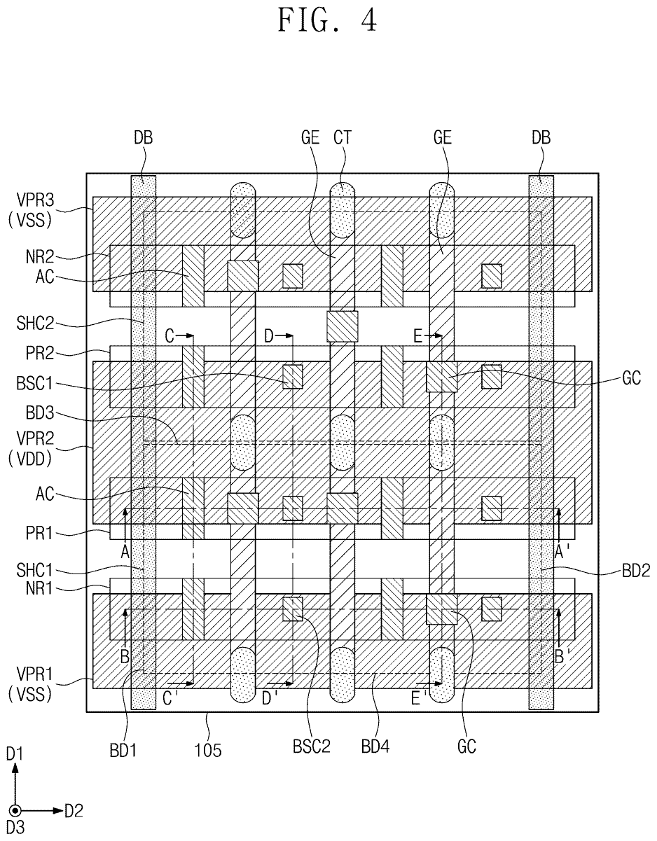

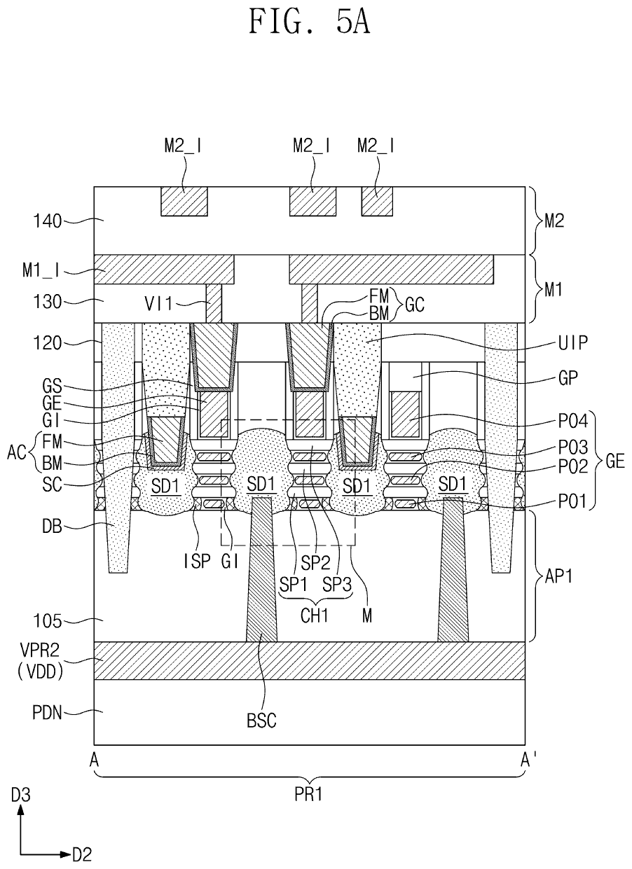

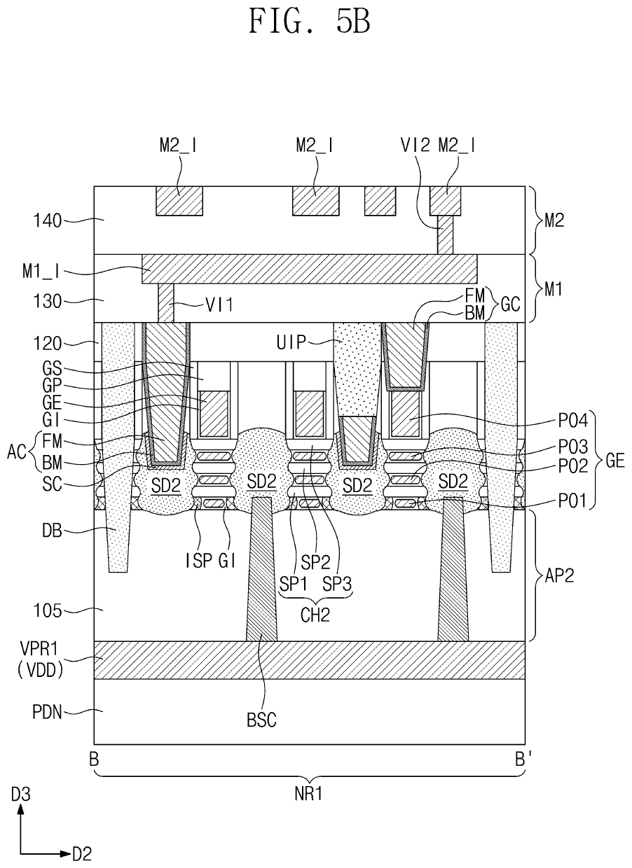

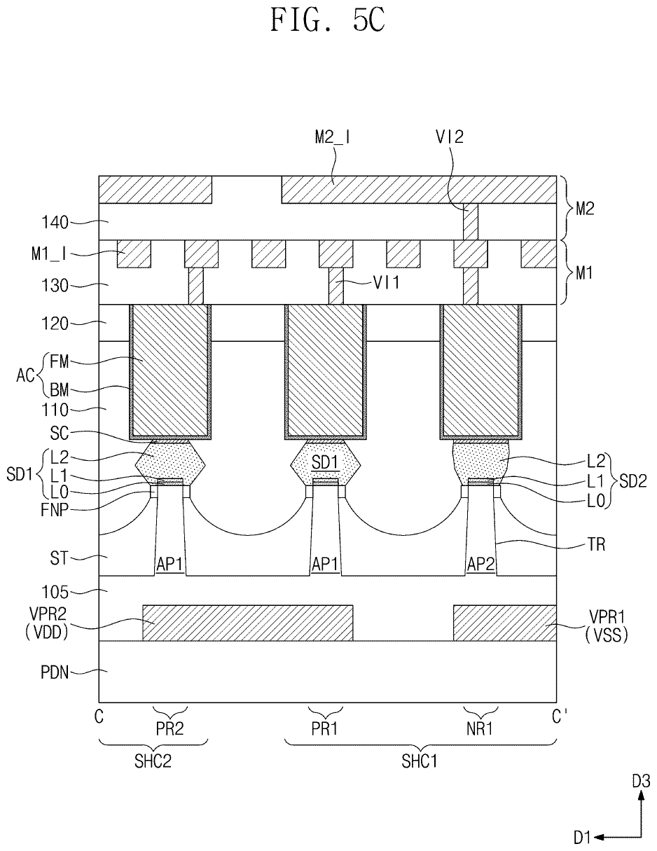

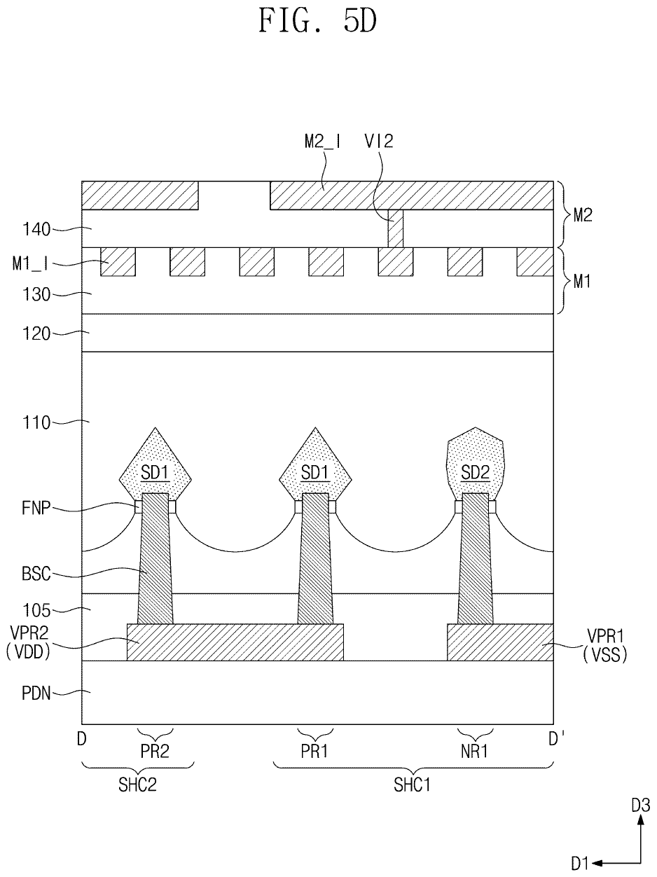

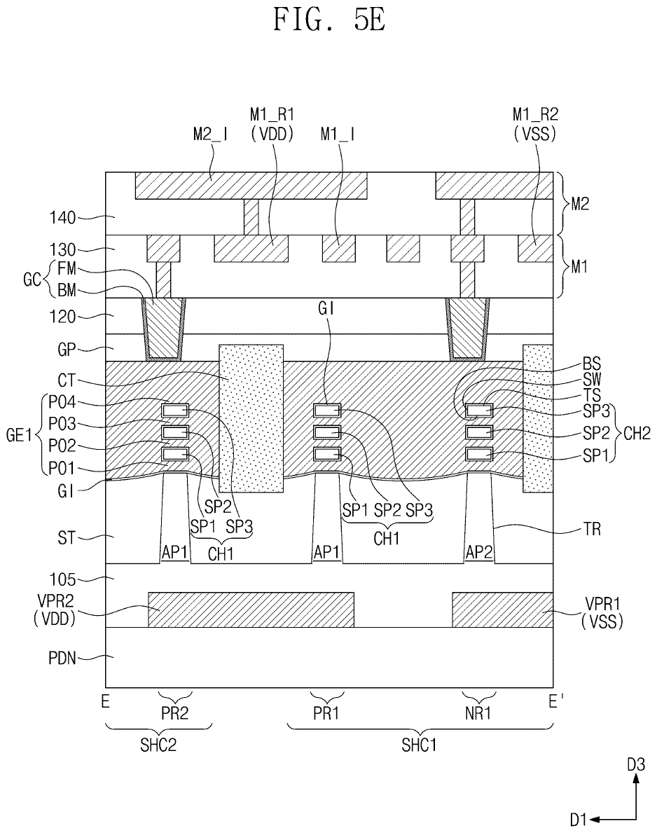

FIG. 4 is a plan view for describing a semiconductor device according to embodiments of the present disclosure. FIGS. 5A to 5E are cross-sectional views taken along a line A-A′, a line B-B′, a line C-C′, a line D-D′, and a line E-E′ of FIG. 4, respectively. In the semiconductor device illustrated in FIG. 4, and 5A to 5E, the first single height cell SHC1 and the second single height cell SHC2 of FIG. 3 are more specifically illustrated.

Referring to FIG. 4, and 5A to 5E, the first single height cell SHC1 and the second single height cell SHC2 may be provided on the substrate 105. Logic transistors that constitute a logic circuit may be disposed on each of the first single height cell SHC1 and the second single height cell SHC2. The substrate 105 may include a silicon-based insulating layer. In other words, the substrate 105 may be an insulating substrate. For example, the substrate 105 may include a silicon oxide layer, a silicon nitride layer, or a silicon oxynitride layer. Lower power wires (e.g., first to third lower power wires VPR1 to VPR3) to be described later may be disposed in an insulating layer of the substrate 105.

The substrate 105 may have the first PMOSFET region PR1, the second PMOSFET region PR2, the first NMOSFET region NR1, and the second NMOSFET region NR2. Each of the first PMOSFET region PR1, the second PMOSFET region PR2, the first NMOSFET region NR1, and the second NMOSFET region NR2 may extend in the second direction D2. The first single height cell SHC1 may include the first NMOSFET region NR1 and the first PMOSFET region PR1, and the second single height cell SHC2 may include the second PMOSFET region PR2 and the second NMOSFET region NR2.

A first insulating pattern AP1 and a second insulating pattern AP2 may define a trench TR formed on an upper portion of the substrate 105. The first insulating pattern AP1 may be provided on each of the first PMOSFET region PR1 and the second PMOSFET region PR2. The second insulating pattern AP2 may be provided on each of the first NMOSFET region NR1 and the second NMOSFET region NR2. The first insulating pattern AP1 and the second insulating pattern AP2 may extend in the second direction D2. The first insulating pattern AP1 and the second insulating pattern AP2 may be, as portions of the substrate 105, parts vertically protruding.

A device separation layer ST may fill the trench TR. The device separation layer ST may cover a sidewall of each of the first insulating pattern AP1 and the second insulating pattern AP2. The device separation layer ST may include a silicon oxide layer. The device separation layer ST may not cover first channel pattern CH1 and the second channel pattern CH2 to be described later.

A first channel pattern CH1 may be provided on the first insulating pattern AP1. A second channel pattern CH2 may be provided on the second insulating pattern AP2. Each of the first channel pattern CH1 and the second channel pattern CH2 may include a first semiconductor pattern SP1, a second semiconductor pattern SP2, and a third semiconductor pattern SP3 sequentially stacked. The first to third semiconductor patterns SP1, SP2, and SP3 may be spaced apart from each other in a vertical direction (e.g., a third direction D3).

Each of the first to third semiconductor patterns SP1, SP2, and SP3 may include silicon (Si), germanium (Ge), or silicon-germanium (SiGe). For example, each of the first to third semiconductor patterns SP1, SP2, and SP3 may include crystalline silicon. Each of the first to third semiconductor patterns SP1, SP2, and SP3 may be a nanosheet.

A plurality of first source/drain patterns SD1 may be provided on the first insulating pattern AP1. A plurality of first recesses may be formed on the first insulating pattern AP1. The first source/drain patterns SD1 may be respectively provided in the first recesses. The first source/drain patterns SD1 may be impurity regions having a first conductive type (e.g., a P-type). The first channel pattern CH1 may be interposed between a pair of first source/drain patterns SD1. In other words, the stacked first to third semiconductor patterns SP1, SP2, and SP3 may connect the pair of first source/drain patterns SD1 each other.

A plurality of second source/drain patterns SD2 may be provided on the second insulating pattern AP2. A plurality of second recesses may be formed on the second insulating pattern AP2. The second source/drain patterns SD2 may be respectively provided in the second recesses. The second source/drain patterns SD2 may be impurity regions having a second conductive type (e.g., an N-type). The second channel pattern CH2 may be interposed between a pair of second source/drain patterns SD2. In other words, the stacked first to third semiconductor patterns SP1, SP2, and SP3 may connect the pair of second source/drain patterns SD2 each other.

The first source/drain pattern SD1 and second source/drain pattern SD2 may be epitaxial patterns formed in a selective epitaxial growth (SEG) process. For example, an upper surface of each of the first source/drain pattern SD1 and second source/drain pattern SD2 may be located at the substantially same level as an upper surface of the third semiconductor pattern SP3. In another example, the upper surface of each of the first source/drain pattern SD1 and second source/drain pattern SD2 may be located at a higher level than the upper surface of the third semiconductor pattern SP3.

The first source/drain patterns SD1 may include a semiconductor element (e.g., SiGe) having a greater lattice parameter than a semiconductor element of the first channel pattern CH1. Accordingly, the pair of the first source/drain patterns SD1 may supply a compressive stress to the first channel pattern CH1 therebetween. The second source/drain patterns SD2 may include the same semiconductor element (e.g., Si) as the semiconductor element of the second channel pattern CH2.

Gate electrodes GE crossing the first channel pattern CH1 and the second channel pattern CH2 and extending in the first direction D1 may be provided. The gate electrodes GE may be arranged with a first pitch in the second direction D2. Each of the gate electrodes GE may vertically overlap with the first channel pattern CH1 and the second channel pattern CH2.

The gate electrode GE may include a first inner part PO1 interposed between the first insulating pattern AP1 or the second insulating pattern AP2 and the first semiconductor pattern SP1, a second inner part PO2 interposed between the first semiconductor pattern SP1 and the second semiconductor pattern SP2, a third inner part PO3 interposed between the second semiconductor pattern SP2 and the third semiconductor pattern SP3, and an outer part PO4 on the third semiconductor pattern SP3.

Referring back to FIG. 5E, the gate electrode GE may be provided on an upper surface TS, a bottom surface BS, and opposite sidewalls SW of each of the first to third semiconductor patterns SP1, SP2, and SP3. In other words, a transistor according to the present embodiment may be a three-dimensional field effect transistor (e.g., a multi-bridge channel field effect transistor (MBCFET) or a gate-all-around field effect transistor (GAAFET)) in which the gate electrode GE three-dimensionally surrounds a channel thereof.

Representatively, the first single height cell SHC1 may have a first boundary BD1 and a second boundary BD2 opposed to each other in the second direction D2. The first boundary BD1 and the second boundary BD2 may extend in the first direction D1. The first single height cell SHC1 may have a third boundary BD3 and a fourth boundary BD4 opposed to each other in the first direction D1. The third boundary BD3 and the fourth boundary BD4 may extend in the second direction D2.

Gate cutting patterns CT may be disposed on a boundary in the second direction D2 of each of the first single height cell SHC1 and the second single height cell SHC2. For example, the gate cutting patterns CT may be disposed on the third boundary BD3 and the fourth boundary BD4 of the first single height cell SHC1. The gate cutting patterns CT may be arranged with the first pitch along the third boundary BD3. The gate cutting patterns CT may be arranged with the first pitch along the fourth boundary BD4. In a plan view, the gate cutting patterns CT on the third boundary BD3 and the fourth boundary BD4 may be disposed respectively overlapping with the gate electrodes GE. The gate cutting patterns CT may include an insulating material such as a silicon oxide layer, a silicon nitride layer, or a combination thereof.

The gate electrode GE on the first single height cell SHC1 may be separated by the gate electrode GE and the gate cutting pattern CT on the second single height cell SHC2. The gate cutting pattern CT may be interposed between the gate electrode GE on the first single height cell SHC1 and the gate electrode GE on the second single height cell SHC2 aligned therewith in the first direction D1. In other words, the gate electrode GE extending in the first direction D1 may be separated into a plurality of gate electrodes GE by the gate cutting patterns CT.

Referring back to FIGS. 4, and 5A to 5E, a pair of gate spacers GS may be respectively disposed on opposite sidewalls of the outer part PO4 of the gate electrode GE. The gate spacers GS may extend along the gate electrode GE in the first direction D1. Upper surfaces of the gate spacers GS may be higher than an upper surface of the gate electrode GE. The upper surfaces of the gate spacers GS may be coplanar with an upper surface of a first interlayered insulating layer 110 to be described later. The gate spacers GS may include at least one from among SiCN, SiCON, and SiN. For another example, the gate spacers GS may include a multi-layer composed of at least two from among SiCN, SiCON, and SiN.

A gate capping pattern GP may be provided on the gate electrode GE. The gate capping pattern GP may extend along the gate electrode GE in the first direction D1. The gate capping pattern GP may include a material having etching selectivity with respect to a first interlayered insulating layer 110 and a second interlayered insulating layer 120 to be described later. Specifically, the gate capping pattern GP may include at least one from among SiON, SiCN, SiCON, and SiN.

A gate insulating layer GI may be interposed between the gate electrode GE and the first channel pattern CH1, and between the gate electrode GE and the second channel pattern CH2. The gate insulating layer GI may cover the upper surface TS, the bottom surface BS, and the opposite sidewalls SW of each of the first to third semiconductor patterns SP1, SP2, and SP3. The gate insulating layer GI may cover an upper surface of the device separation layer ST under the gate electrode GE. The gate insulating layer GI may be interposed between the first inner part PO1 and the first insulating pattern AP1 and the second insulating pattern AP2.

According to an embodiment of the present disclosure, the gate insulating layer GI may include a silicon oxide layer, a silicon oxynitride layer, and/or a high dielectric layer. The high dielectric layer may include a material having a higher dielectric constant than a dielectric constant of the silicon oxide layer. For example, the material having a higher dielectric constant than the dielectric constant of the silicon oxide layer may include at least one from among hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, and lead zinc niobate.

The gate electrode GE may include a first metal pattern, and a second metal pattern on the first metal pattern. The first metal pattern may be provided on the gate insulating layer GI to be adjacent to the first to third semiconductor patterns SP1, SP2, and SP3. The first metal pattern may include a work-function metal that controls a threshold voltage of a transistor. A targeted threshold voltage of the transistor may be achieved by controlling a thickness and a composition of the first metal pattern. For example, the first to third inner parts PO1, PO2, and PO3 of the gate electrode GE may be composed of the first metal pattern, which may be made of the work-function metal.

The first metal pattern may include a metal nitride layer. For example, the first metal pattern may include nitrogen (N) and at least one metal selected from the group consisting of titanium (Ti), tantalum (Ta), aluminum (Al), tungsten (W), and molybdenum (Mo). Moreover, the first metal pattern may further include carbon (C). The first metal pattern may include a plurality of stacked work-function metal layers.

The second metal pattern may include a metal having a lower resistance (e.g., an electrical resistance) than a resistance (e.g., an electrical resistance) of the first metal pattern. For example, the second metal pattern may include at least one metal selected from the group consisting of titanium (Ti), tantalum (Ta), aluminum (Al), and tungsten (W). For example, the outer part PO4 of the gate electrode GE may include the first metal pattern and the second metal pattern on the first metal pattern.

The first interlayered insulating layer 110 may be provided on the substrate 105. The first interlayered insulating layer 110 may cover the gate spacers GS, the first source/drain pattern SD1, and second source/drain pattern SD2. An upper surface of the first interlayered insulating layer 110 may be substantially coplanar with an upper surface of the gate capping pattern GP and an upper surface of the gate spacer GS. The second interlayered insulating layer 120 covering the gate capping pattern GP may be disposed on the first interlayered insulating layer 110. A third interlayered insulating layer 130 may be provided on the second interlayered insulating layer 120. A fourth interlayered insulating layer 140 may be provided on the third interlayered insulating layer 130. For example, the first to fourth interlayered insulating layers 110, 120, 130, and 140 may each include a silicon oxide layer.

A pair of separation structures DB opposed to each other in the second direction D2 may be provided at opposite sides of each of the first single height cell SHC1 and the second single height cell SHC2. For example, the pair of separation structures DB may be respectively provided on the first boundary BD1 and the second boundary BD2 of the first single height cell SHC1. The separation structure DB may extend parallel to the gate electrodes GE in the first direction D1.

The separation structure DB may penetrate the gate capping pattern GP and the gate electrode GE to extend into the first insulating pattern AP1 and the second insulating pattern AP2. The separation structure DB may penetrate an upper portion of the first insulating pattern AP1 and the second insulating pattern AP2. The separation structure DB may electrically separate an active region of each of the first single height cell SHC1 and the second single height cell SHC2 from an active region of another cell adjacent thereto.

Active contacts AC penetrating the first interlayered insulating layer 110 and the second interlayered insulating layer 120 to be respectively electrically connected to the first source/drain pattern SD1 and second source/drain pattern SD2 may be provided. Each of the active contacts AC may be provided so as to be adjacent to one side of the gate electrode GE. In a plan view, the active contact AC may have a form of a bar extending in the first direction D1.

The active contact AC may be a self-aligned contact. In other words, the active contact AC may be formed self-aligned using the gate capping pattern GP and the gate spacer GS. For example, the active contact AC may at least partially cover sidewalls of the gate spacer GS. According to some embodiments, the active contact AC may partially cover an upper surface of the gate capping pattern GP.

A metal-semiconductor compound layer SC (e.g., a silicide layer) may be interposed between the active contact AC and the first source/drain pattern SD1, and between the active contact AC and the second source/drain pattern SD2. The active contact AC may be electrically connected to the first source/drain pattern SD1 or the second source/drain pattern SD2 through the metal-semiconductor compound layer SC. For example, the metal-semiconductor compound layer SC may include at least one from among titanium-silicide, tantalum-silicide, tungsten-silicide, nickel-silicide, and cobalt-silicide.

Gate contacts GC penetrating the second interlayered insulating layer 120 and the gate capping pattern GP to be respectively electrically connected to the gate electrodes GE may be provided. In a plan view, two gate contacts GC on the first single height cell SHC1 may be disposed so as to overlap with the first PMOSFET region PR1. In other words, two gate contacts GC on the first single height cell SHC1 may be provided on the first insulating pattern AP1 (see FIG. 5A). In a plan view, one gate contact GC on the first single height cell SHC1 may be disposed so as to overlap with the first NMOSFET region NR1. In other words, one gate contact GC on the first single height cell SHC1 may be provided on the second insulating pattern AP2 (see FIG. 5B).

The gate contact GC may be freely disposed on the gate electrode GE without limitation of a position. For example, the gate contacts GC on the second single height cell SHC2 may be respectively disposed on the second PMOSFET region PR2, the second NMOSFET region NR2, and the device separation layer ST that fills the trench TR (see FIG. 4).

An upper portion of the active contact AC adjacent to the gate contact GC may be filled with an upper insulating pattern UIP. The upper insulating pattern UIP may have a bottom surface that is lower than a bottom surface of the gate contact GC. In other words, an upper surface of the active contact AC adjacent to the gate contact GC may become lower than a bottom surface of the gate contact GC due to the upper insulating pattern UIP. Accordingly, an electric short occurring when the gate contact GC is in contact with the active contact AC adjacent thereto may be prevented. For example, the upper insulating pattern UIP may include a silicon-based insulating material (e.g., a silicon oxide layer, a silicon nitride layer, or a silicon oxynitride layer).

Each of the active contact AC and the gate contact GC may include a conductive pattern FM and a barrier pattern BM surrounding the conductive pattern FM. For example, the conductive pattern FM may include at least one metal from among aluminum, copper, tungsten, molybdenum, and cobalt. The barrier pattern BM may cover sidewalls and a bottom surface of the conductive pattern FM. The barrier pattern BM may include a metal layer/metal nitride layer. The metal layer may include at least one from among titanium, tantalum, tungsten, nickel, cobalt, and platinum. The metal nitride layer may include at least one from among a titanium nitride (TiN) layer, a tantalum nitride (TaN) layer, a tungsten nitride (WN) layer, a nickel nitride (NiN) layer, a cobalt nitride (CoN) layer, and a platinum nitride (PtN) layer.

Referring back to FIGS. 4, and 5C to 5E, the first to third lower power wires VPR1, VPR2, and VPR3 may be provided in a lower portion of the substrate 105. The first to third lower power wires VPR1, VPR2, and VPR3 may extend parallel to each other in the second direction D2. The first lower power wire VPR1 may be disposed on the fourth boundary BD4 of the first single height cell SHC1. The second lower power wire VPR2 may be disposed on the third boundary BD3 of the first single height cell SHC1. In other words, the first single height cell SHC1 may be defined by and between the first lower power wire VPR1 and the second lower power wire VPR2. The second single height cell SHC2 may be defined by and between the second lower power wire VPR2 and the third lower power wire VPR3.

According to an embodiment of the present disclosure, the first lower power wire VPR1 may vertically overlap with the first NMOSFET region NR1. The second lower power wire VPR2 may vertically overlap with the first PMOSFET region PR1 and the second PMOSFET region PR2. The third lower power wire VPR3 may vertically overlap with the second NMOSFET region NR2.

The first to third lower power wires VPR1, VPR2, and VPR3 may include at least one selected from the group consisting of copper, molybdenum, tungsten, and ruthenium. A bottom surface of each of the first to third lower power wires VPR1, VPR2 and VPR3 may be coplanar with a bottom surface of the substrate 105.

A power transmission network layer PDN may be provided on the bottom surface of the substrate 105. The power transmission network layer PDN may include a plurality of lower wires electrically connected to the first to third lower power wires VPR1, VPR2, and VPR3. For example, the power transmission network layer PDN may include a wire network for applying the source voltage VSS to the first lower power wire VPR1 and the third lower power wire VPR3. The power transmission network layer PDN may include a wire network for applying the drain voltage VDD to the second lower power wire VPR2.

Referring back to FIGS. 4, 5A, 5B and 5D, a backside contact BSC (e.g., a first backside contact BSC1) may penetrate the substrate 105 to vertically extend from the second lower power wire VPR2 to the first source/drain pattern SD1. A backside contact BSC (e.g., a second backside contact BSC2) may penetrate the substrate 105 to vertically extend from the first lower power wire VPR1 to the second source/drain pattern SD2. A width in the second direction D2 of the backside contact BSC may decrease in a vertical direction D3 that extends upwards from the bottom surface of the substrate 105.

The backside contact BSC on the PMOSFET region PR may have a form of a conductive pillar vertically and electrically connecting the second lower power wire VPR2 and the first source/drain pattern SD1. The drain voltage VDD may be applied to the first source/drain pattern SD1 through the backside contact BSC.

The backside contact BSC on the NMOSFET region NR may have a form of a conductive pillar vertically and electrically connecting the first lower power wire VPR1 and the second source/drain pattern SD2. The source voltage VSS may be applied to the second source/drain pattern SD2 through the backside contact BSC.

Referring back to FIGS. 4, and 5A to 5E, a first metal layer M1 may be provided in the third interlayered insulating layer 130. The first metal layer M1 may include first wires M1_I. The first wires M1_I of the first metal layer M1 may extend parallel to each other in the second direction D2.

According to embodiments of the present disclosure, a power wire for supplying power to the single height cell SHC may be buried in the substrate 105 in a form of the lower power wire (e.g., the first lower power wire VPR1, the second lower power wire VPR2, or the third lower power wire VPR3). Accordingly, the power wire may be omitted in the first metal layer M1. The first wires M1_I for signal transmission may be disposed in the first metal layer M1.

The first metal layer M1 may further include first vias VI1. The first vias VI1 may be respectively provided under the first wires M1_I of the first metal layer M1. The active contact AC and the first wire M1_I of the first metal layer M1 may be electrically connected to each other through the first via VI1. The gate contact GC and the first wire M1_I of the first metal layer M1 may be electrically connected to each other through the first via VI1.

The first wire M1_I of the first metal layer M1 and the first via VI1 thereunder may be respectively formed in separate processes. In other words, each of the first wire M1_I of the first metal layer M1 and the first via VI1 may be formed in a single damascene process. The semiconductor device according to the present embodiment may be formed using a process of manufacturing a semiconductor device having a design rule less than about 20 nm. As used herein, the design rule less than about 20 nm may indicate that the critical dimensions (CD) of features such as metal line width is less than about 20 nm.

A second metal layer M2 may be provided in the fourth interlayered insulating layer 140. The second metal layer M2 may include a plurality of second wires M2_I. Each of the second wires M2_I of the second metal layer M2 may have a form of a line or a bar extending in the first direction D1. In other words, the second wires M2_I may extend parallel to each other in the first direction D1.

The second metal layer M2 may further include second vias VI2 respectively provided under the second wires M2_I. The first wire M1_I of the first metal layer M1 and the second wire M2_I of the second metal layer M2 may be electrically connected to each other through the second via VI2. For example, the second wire M2_I of the second metal layer M2 and the second via VI2 thereunder may be formed together in a dual damascene process.

The first wire M1_I of the first metal layer M1 and the second wire M2_I of the second metal layer M2 may include the same conductive material as each other or different conductive materials from each other. For example, the first wire M1_I of the first metal layer M1 and the second wire M2_I of the second metal layer M2 may include at least one metal material selected from aluminum, copper, tungsten, molybdenum, ruthenium, and cobalt. According to some embodiments, metal layers (e.g., metals layers on the second metal layer M2) stacked on the fourth interlayered insulating layer 140 may be additionally disposed. Each of the stacked metal layers may include wires for routing between cells.

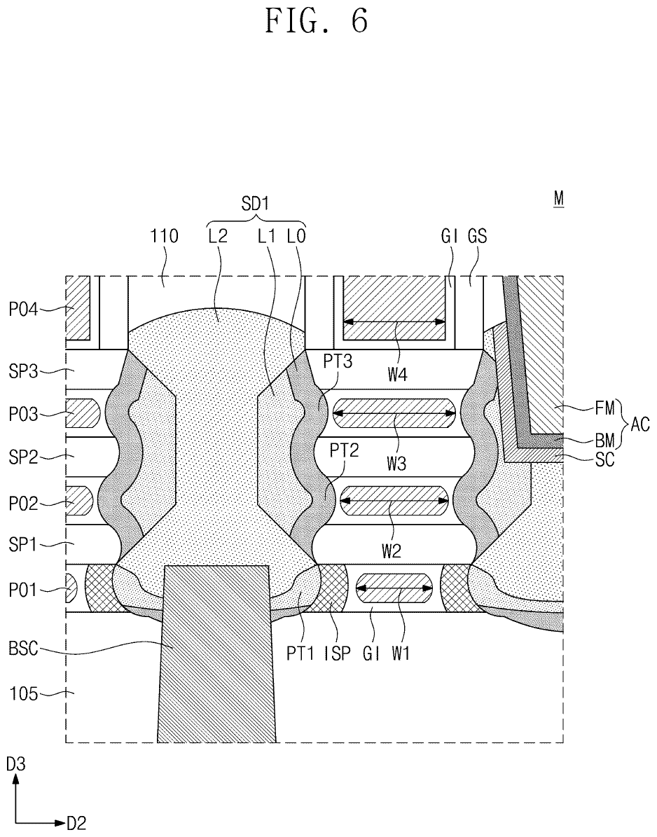

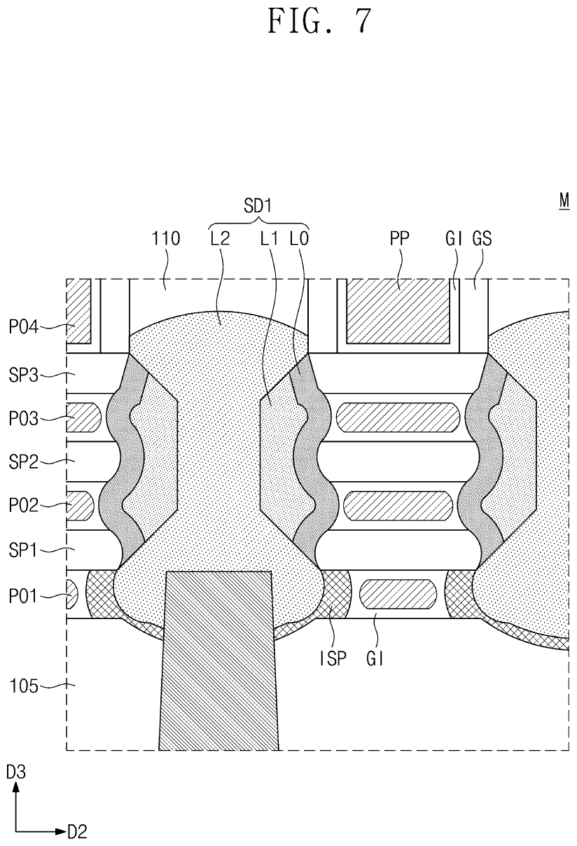

FIG. 6 is an enlarged diagram illustrating an embodiment of a region M of FIG. 5A. The first source/drain pattern SD1 and the gate electrode GE will be described with reference to FIG. 6 in more detail. Descriptions with reference to FIG. 6 may be substantially identically applied to the second source/drain pattern SD2.

Referring to FIG. 6, an inner spacer ISP may be interposed between the first source/drain pattern SD1 and the first inner part PO1 of the gate electrode GE. One surface of the inner spacer ISP may be in contact with the first source/drain pattern SD1, and another surface of the inner spacer ISP may be in contact with the gate insulating layer GI surrounding the first inner part PO1. The one surface of the inner spacer ISP may be a concave surface recessed toward the first inner part PO1. The other surface of the inner spacer ISP may be a convex surface toward the first inner part PO1.

The inner spacer ISP may include an insulating material. For example, the inner spacer ISP may include at least one from among SiN, SiCN, SiON, SiBCN and SiOCN. For another example, the inner spacer ISP may include a multi-layer composed of at least two from among SiN, SiCN, SiON, SiBCN and SiOCN. For another example, the inner spacer ISP may include a Si-containing insulating material.

The inner spacer ISP may not be provided between the second inner part PO2 and the first source/drain pattern SD1 and between the third inner part PO3 and the first source/drain pattern SD1. Accordingly, a first layer L0 of the first source/drain pattern SD1, to be described later, may be formed well without a void and a crack.

The first inner part PO1 may have a first width W1 in the second direction D2. The second inner part PO2 may have a second width W2 in the second direction D2. The third inner part PO3 may have a third width W3 in the second direction D2. The outer part PO4 may have a fourth width W4 in the second direction D2.

The first width W1 may be smaller than the second width W2, the third width W3, and the fourth width W4. In other words, the width of the first inner part PO1 may be smaller than the widths of the second inner part PO2, the third inner part PO3, and the outer part PO4. This is because the inner spacers ISP are respectively provided on opposite sides of the first inner part PO1. The first width W1 may be substantially the same as or smaller than the fourth width W4. Meanwhile, the second width W2 and the third width W3 may be greater than the fourth width W4. Specifically, a minimum width of the second inner part PO2 and a minimum width of the third inner part PO3 may be greater than the width of the outer part PO4.

The first source/drain pattern SD1 may include the first layer L0 in direct contact with the first to third semiconductor patterns SP1, SP2, and SP3, a second layer L1 on the first layer L0, and a third layer L2 on the second layer L1. The third layer L2 may have a larger volume than a volume of the first layer L0 and a volume of the second layer L1.

The first to third layers L0, L1 and L2 may include silicon-germanium (SiGe). The first layer L0 may include germanium (Ge) at a relatively low concentration. The first layer L0 may contain only silicon (Si) and germanium (Ge). The second layer L1 may have a higher germanium (Ge) concentration than the first layer L0. The second layer L1 may have a germanium (Ge) concentration of about 15 at % to about 40 at %, but an embodiment of the present disclosure is not limited thereto.

The third layer L2 may have a higher germanium (Ge) concentration than a germanium (Ge) concentration of the second layer L1. The third layer L2 may contain germanium (Ge) at a relatively high concentration. The third layer L2 may have a germanium (Ge) concentration of about 30 at % to about 70 at %, but an embodiment of the present disclosure is not limited thereto.

The first to third layers L0, L1 and L2 may include an impurity (e.g., boron, gallium, or indium) that makes the first source/drain pattern SD1 have a P-type. Each of the first to third layers L0, L1 and L2 may have an impurity concentration of about 1E18 atom/cm³ to about 5E22 atom/cm³. The third layer L2 may have a greater impurity concentration than an impurity concentration of the second layer L1. The second layer L1 may have a greater impurity concentration than an impurity concentration of the first layer L0.

In another example, in a case of the second source/drain pattern SD2, the first to third layers L0, L1 and L2 may further include an impurity (e.g., phosphorous, arsenic, or antimony) that makes the second source/drain pattern SD2 have an N-type. The second source/drain pattern SD2 may have an impurity concentration of about 1E18 atom/cm³ to about 5E22 atom/cm³.

The third layer L2 may have an hourglass profile. The third layer L2 may have an upper portion, a lower portion, and a central portion between the upper portion and the lower portion. The upper portion and the lower portion of the third layer L2 may have a fan-shaped profile. The upper portion of the third layer L2 may cover an upper surface of each of the first layer L0 and the second layer L1. The lower portion of the third layer L2 may cover a lower surface of each of the first layer L0 and the second layer L1. The central portion of the third layer L2 may extend in the third direction D3. The central portion of the third layer L2 may be surrounded by the first layer L0 and the second layer L1. A width of the upper portion of the third layer L2 may decrease in a direction towards the central portion thereof. A width of the lower portion of the third layer L2 may increase in a direction away from the central portion thereof.

The first layer L0 and the second layer L1 may be additionally provided between the substrate 105 and the lower surface of the third layer L2. Specifically, the second layer L1 may be provided under the lower surface of the third layer L2, and the first layer L0 may be provided under a lower surface of the second layer L1. Each of the first layer L0 and the second layer L1 provided under the lower surface of the third layer L2 may be in at least partial contact with one surface of the inner spacer ISP. The lower portion of the third layer L2 may be in at least partial contact with one surface of the inner spacer ISP.

The first source/drain pattern SD1 may have a wavy profile by including a part protruding toward the gate electrode GE. The first source/drain pattern SD1 may include a first part PT1 protruding toward the first inner part PO1, a second part PT2 protruding toward the second inner part PO2, and a third part PT3 protruding toward the third inner part PO3. The first part PT1 may be in contact with one surface of the inner spacer ISP.

The first part PT1 may have a higher germanium (Ge) concentration than a germanium (Ge) concentration of the second part PT2 and a germanium (Ge) concentration of the third part PT3. For example, the second part PT2 and the third part PT3 may be portions of the first layer L0, and the first part PT1 may be a portion of the second layer L1 or the third layer L2. This is because the second part PT2 and the third part PT3 are located between the first to third semiconductor patterns SP1, SP2, and SP3 forming the first layer L0 in a manufacturing method to be described later. Meanwhile, since the first part PT1 is adjacent to the inner spacer ISP, the first part PT1 may be a portion of the second layer L1 and/or the third layer L2, not the first layer L0.

The backside contact BSC may be connected to the lower portion of the third layer L2. The backside contact BSC may be connected to the third layer L2 having a high concentration to improve resistance (e.g., electrical resistance) of the rear surface contact BSC. The backside contact BSC may be spaced apart from the first inner part PO1 in the second direction D2 with the inner spacer ISP and the gate insulating layer GI therebetween. Accordingly, even when the backside contact BSC is formed slightly away in the second direction D2, a distance between the backside contact BSC and the first inner part PO1 may be maintained by the inner spacer ISP and the gate insulating layer GI. The distance between the first inner part PO1 and the backside contact BSC may be increased by forming the inner spacer ISP, and thus an electric short and leakage current therebetween may be prevented.

FIG. 7 is an enlarged diagram illustrating an embodiment of the region M of FIG. 5A. Detailed duplicate descriptions for technological features made with reference to FIG. 6 may be omitted, and differences will be described in detail.

Referring to FIG. 7, the inner spacer ISP may extend under a lower surface of the first source/drain pattern SD1. Specifically, the inner spacer ISP may extend between the substrate 105 and a bottom surface of the first source/drain pattern SD1. The inner spacer ISP may be in contact with a side surface of the backside contact BSC. The backside contact BSC may penetrate the inner spacer ISP to be connected to the first source/drain pattern SD1.

The first layer L0 and the second layer L1 may not be provided between the substrate 105 and the third layer L2, unlike in FIG. 6. This is because in the manufacturing method to be described later, since the inner spacer ISP covers an upper surface of a semiconductor substrate 100, the first layer L0 and the second layer L1 are not formed on a lower portion of the first source/drain pattern SD1. Accordingly, the inner spacer ISP may be in contact with the third layer L2.

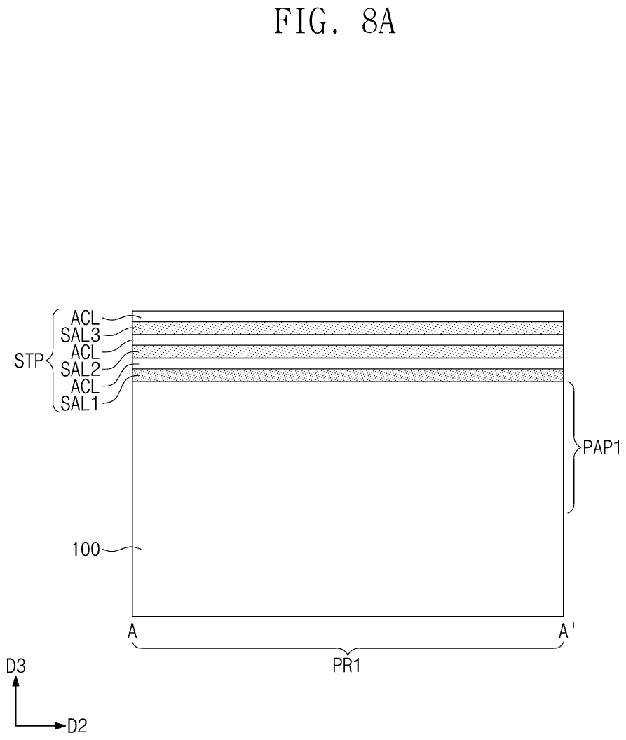

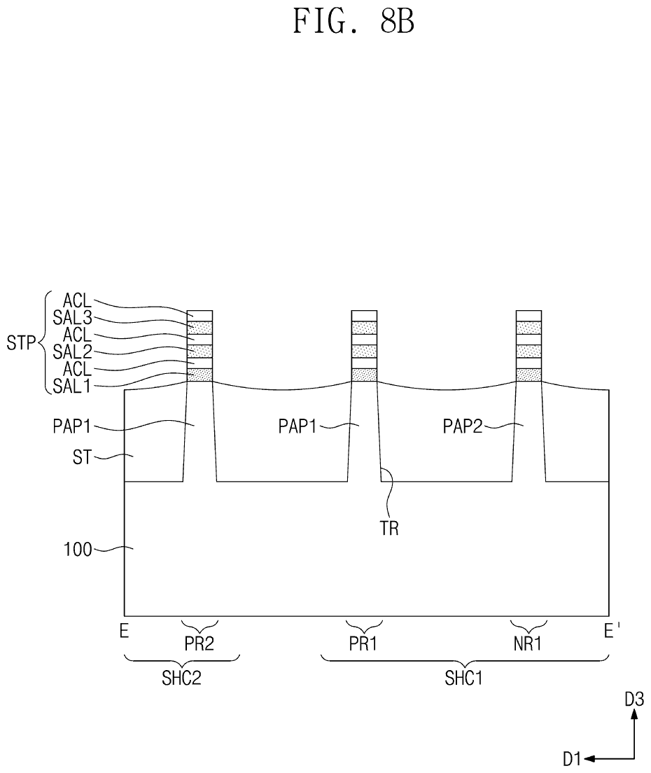

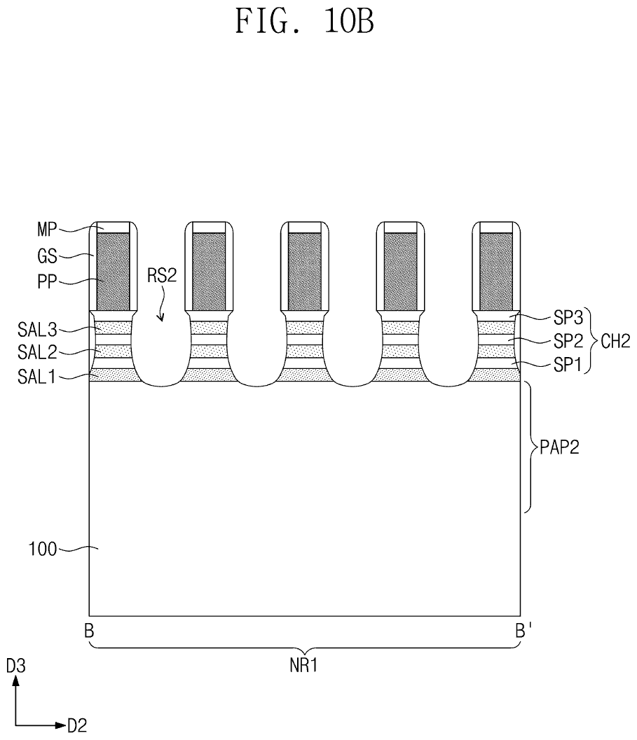

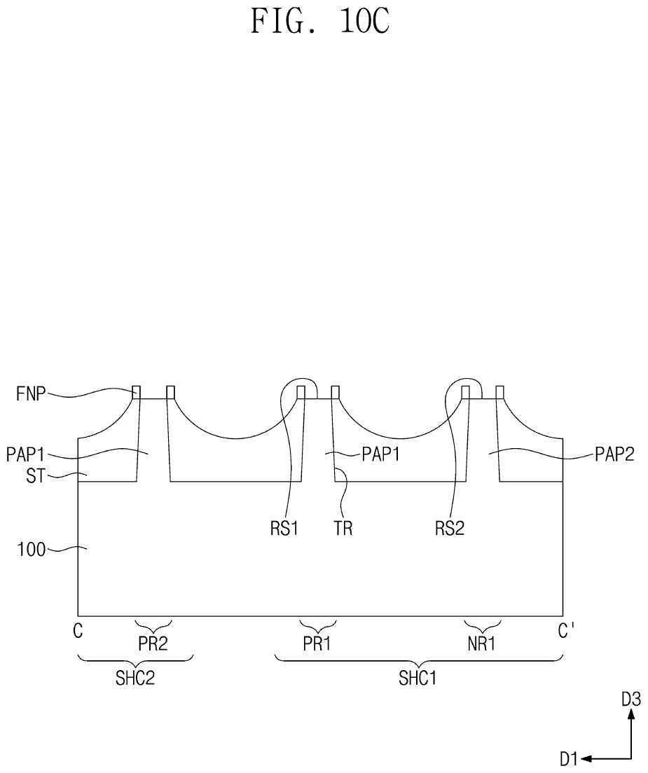

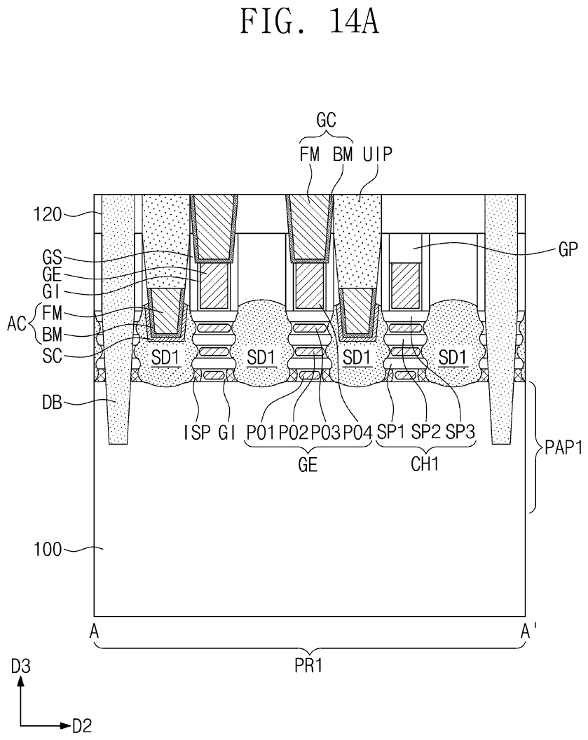

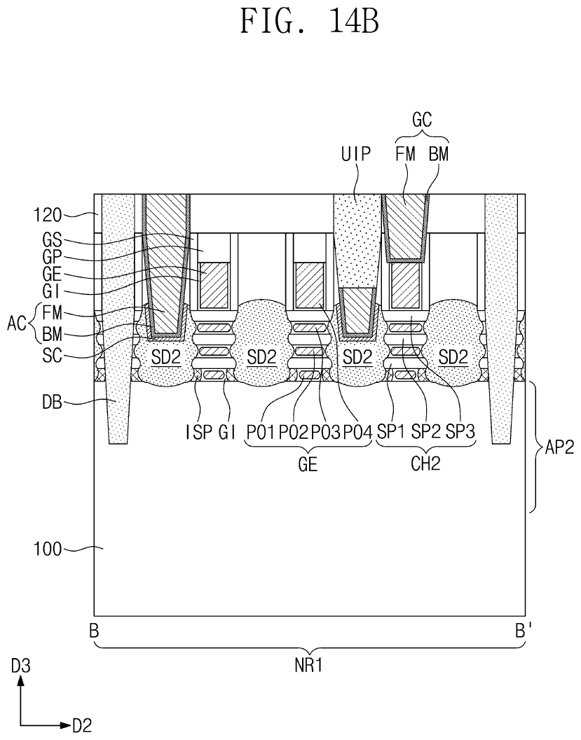

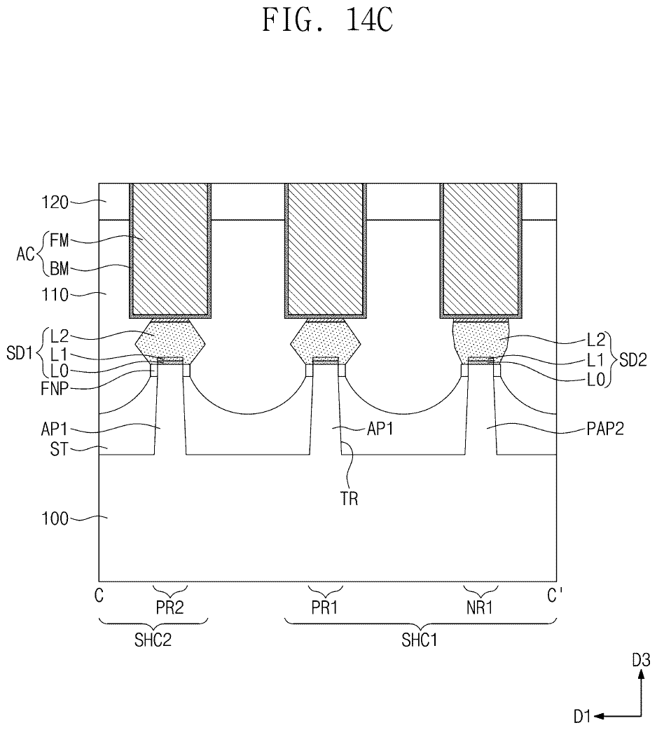

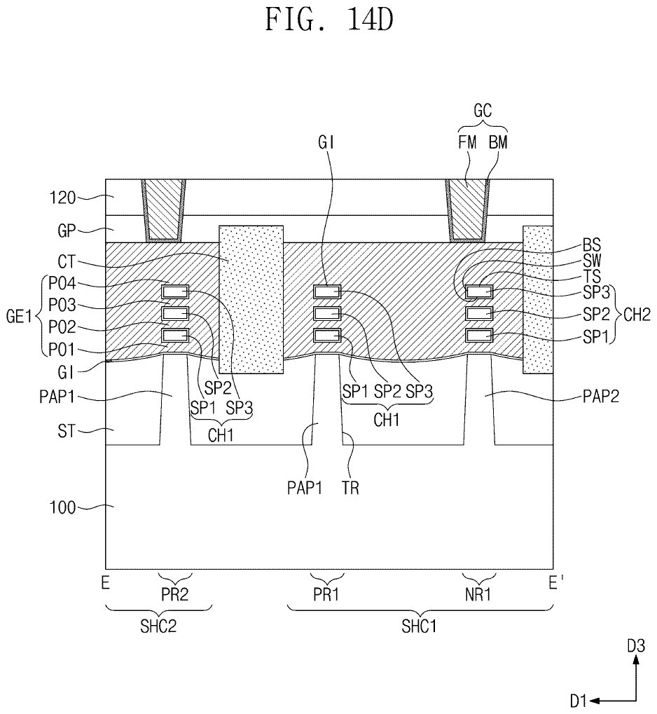

FIGS. 8A to 16B are cross-sectional views for describing a method for manufacturing a semiconductor device according to embodiments of the present disclosure. Specifically, FIGS. 8A, 9A, 10A, 11A, 12A, 13, 14A, 15A and 16A are cross-sectional views corresponding to the line A-A′ of FIG. 4. FIGS. 10B and 14B are cross-sectional views corresponding to the line B-B′ of FIG. 4. FIGS. 10C, 11B and 14C are cross-sectional views corresponding to the line C-C′ of FIG. 4. FIGS. 14D, 15B and 16B are cross-sectional views corresponding to the line D-D′ of FIG. 4. FIGS. 8B, 9B and 12B are cross-sectional views corresponding to the line E-E′ of FIG. 4.

Referring to FIGS. 8A and 8B, the semiconductor substrate 100 including the first PMOSFET region PR1, the second PMOSFET region PR2, the first NMOSFET region NR1, and the second NMOSFET region NR2 may be provided. For example, the semiconductor substrate 100 may be a silicon wafer.

First semiconductor layers ACL and second semiconductor layers (e.g., a first sacrificial layer SAL1, a second sacrificial layer SAL2, a third sacrificial layer SAL3) alternately stacked may be formed on the semiconductor substrate 100. The first semiconductor layers ACL may include one from among silicon (Si), germanium (Ge), and silicon-germanium (SiGe), and the second semiconductor layers (e.g., the first sacrificial layer SAL1, the second sacrificial layer SAL2, and the third sacrificial layer SAL3) may include another one from among silicon (Si), germanium (Ge), and silicon-germanium (SiGe).

The second semiconductor layer (e.g., the first sacrificial layer SAL1, the second sacrificial layer SAL2, and the third sacrificial layer SAL3) may include a material having etching selectivity with respect to the first semiconductor layer ACL. For example, the first semiconductor layers ACL may include silicon (Si), and the second semiconductor layers (e.g., the first sacrificial layer SAL1, the second sacrificial layer SAL2, and the third sacrificial layer SAL3) may include silicon-germanium (SiGe). Each of the second semiconductor layers (e.g., the first sacrificial layer SAL1, the second sacrificial layer SAL2, and the third sacrificial layer SAL3) may have a germanium (Ge) concentration of about 10 at % to about 35 at %.

The second semiconductor layers may include a first sacrificial layer SAL1, a second sacrificial layer SAL2 and a third sacrificial layer SAL3 sequentially stacked. The first sacrificial layer SAL1 may be a lowermost layer among the second semiconductor layers. The first sacrificial layer SAL1 may include a material different from materials of the second sacrificial layer SAL2 and the third sacrificial layer SAL3. The first sacrificial layer SAL1 may have a greater germanium (Ge) concentration than a germanium (Ge) concentration of the second sacrificial layer SAL2 and a germanium (Ge) concentration of the third sacrificial layer SAL3. The first sacrificial layer SAL1 may include a material having etching selectivity with respect to the second sacrificial layer SAL2 and the third sacrificial layer SAL3.

Mask patterns may be respectively formed on the first PMOSFET region PR1 and the second PMOSFET region PR2 and the first NMOSFET region NR1 and the second NMOSFET region NR2 of the semiconductor substrate 100. The mask pattern may have a form of a line or a bar extending in the second direction D2.

The trench TR defining a first active pattern PAP1 and a second active pattern PAP2 may be formed by performing a patterning process using the mask patterns as etching masks. The first active pattern PAP1 may be formed on each of the first PMOSFET region PR1 and the second PMOSFET region PR2. The second active pattern PAP2 may be formed on each of the first NMOSFET region NR1 and the second NMOSFET region NR2. In a plan view, the first active pattern PAP1 and the second active pattern PAP2 may have forms of lines extending parallel to each other in the second direction D2.

A stack pattern STP may be formed on each of the first active pattern PAP1 and the second active pattern PAP2. The stack pattern STP may include the first semiconductor layers ACL and the second semiconductor layers (e.g., the first sacrificial layer SAL1, the second sacrificial layer SAL2, and the third sacrificial layer SAL3) alternately stacked on the first active pattern PAP1 and the second active pattern PAP2. The stack pattern STP may be formed together with the first active pattern PAP1 and the second active pattern PAP2 during the patterning process.

The device separation layer ST that fills the trench TR may be formed. Specifically, an insulating layer covering the first active pattern PAP1, the second active pattern PAP2, and the stack patterns STP may be formed on a front surface of the semiconductor substrate 100. The device separation layer ST may be formed by recessing the insulating layer until the stack patterns STP are exposed.

The device separation layer ST may include an insulating material such as a silicon oxide layer. The stack patterns STP may be exposed onto the device separation layer ST. In other words, the stack patterns STP may vertically protrude on the device separation layer ST.

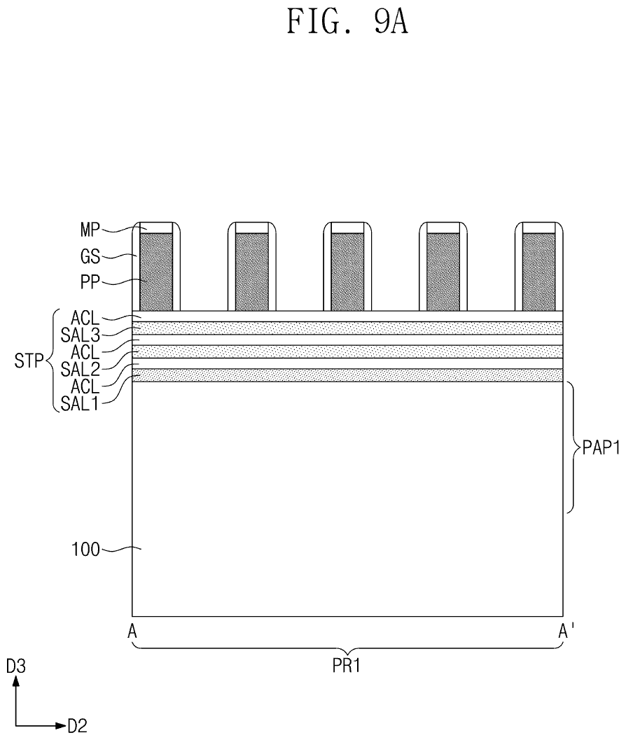

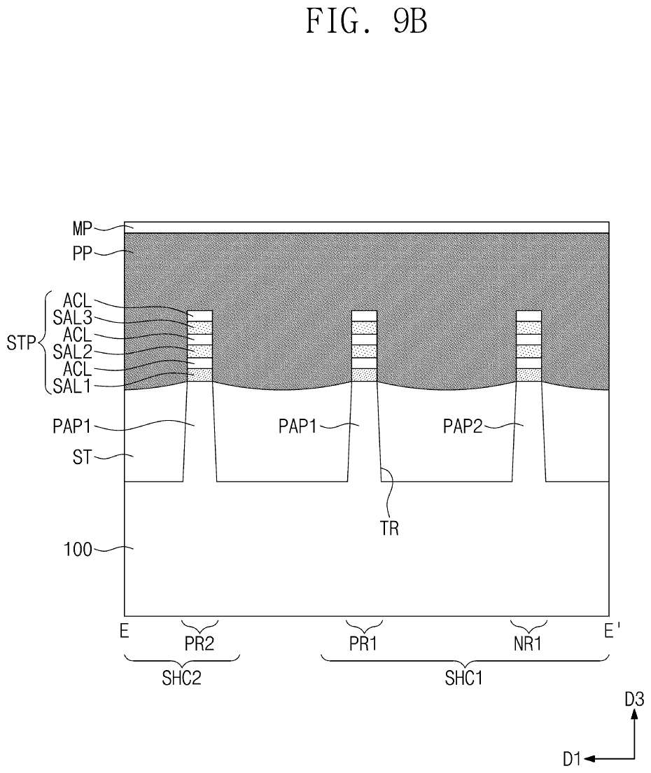

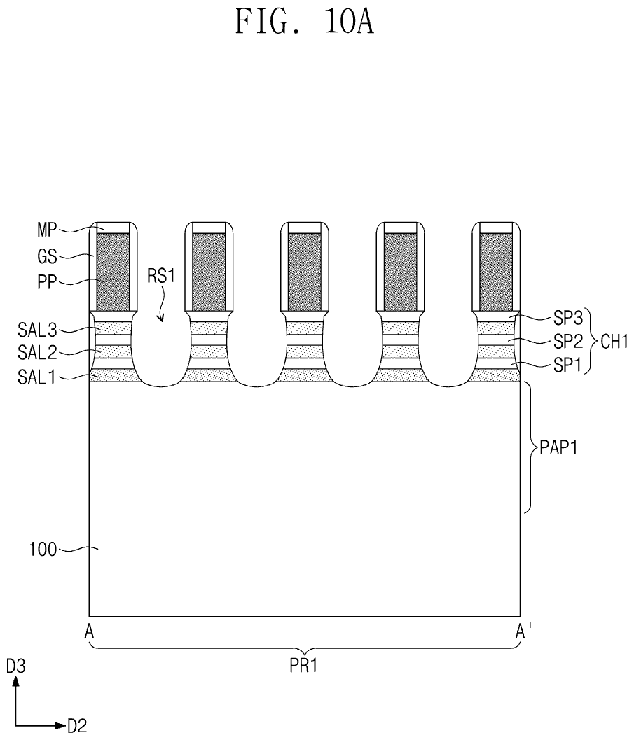

Referring to FIGS. 9A and 9B, sacrificial patterns PP crossing the stack patterns STP may be formed on the semiconductor substrate 100. Each of the sacrificial patterns PP may be formed in a shape of a line or a bar extending in the first direction D1. The sacrificial patterns PP may be arranged with a first pitch along the second direction D2.

Specifically, forming the sacrificial patterns PP may include forming a sacrificial layer on the front surface of the semiconductor substrate 100, forming hard-mask patterns MP on the sacrificial layer, and patterning the sacrificial layer using the hard-mask patterns MP as etching masks. The sacrificial layer may include polysilicon.

A pair of gate spacers GS may be formed on both sidewalls of each of the sacrificial patterns PP. Forming the gate spacers GS may include conformally forming a gate spacer layer on the front surface of the semiconductor substrate 100, and anisotropically etching the gate spacer layer. The gate spacer layer may include at least one from among SiCN, SiCON, and SiN. In another example, the gate spacer layer may be a multi-layer including at least two from among SiCN, SiCON, and SiN.

Referring to FIGS. 10A to 10C, first recesses RS1 may be formed in the stack pattern STP on the first active pattern PAP1. Second recesses RS2 may be formed in the stack pattern STP on the second active pattern PAP2. While the first recess RS1 and the second recess RS2 are formed, portions of the device separation layer ST on opposite sides of each of the first active pattern PAP1 and the second active pattern PAP2 may be further recessed (see FIG. 10C).

Specifically, the first recesses RS1 may be formed by etching the stack pattern STP on the first active pattern PAP1 using the hard-mask patterns MP and the gate spacers GS as etching masks. The first recess RS1 may be formed between a pair of sacrificial patterns PP. The second recesses RS2 in the stack pattern STP on the second active pattern PAP2 may be formed in the same process as a process of forming the first recesses RS1.

Referring back to FIG. 10C, a fence pattern FNP may be formed on each of the first active pattern PAP1 and the second active pattern PAP2. The fence pattern FNP may be a part of a remaining portion of the gate spacer GS.

Referring back to FIGS. 10A to 10C, the first to third semiconductor patterns SP1, SP2, and SP3 sequentially stacked between the first recesses RS1 adjacent to each other may be respectively formed from the first semiconductor layers ACL. The first to third semiconductor patterns SP1, SP2, and SP3 sequentially stacked between the second recesses RS2 adjacent to each other may be respectively formed from the first semiconductor layers ACL. The first to third semiconductor patterns SP1, SP2, and SP3 between the first recesses RS1 adjacent to each other may constitute the first channel pattern CH1. The first to third semiconductor patterns SP1, SP2, and SP3 between the second recesses RS2 adjacent to each other may constitute the second channel pattern CH2.

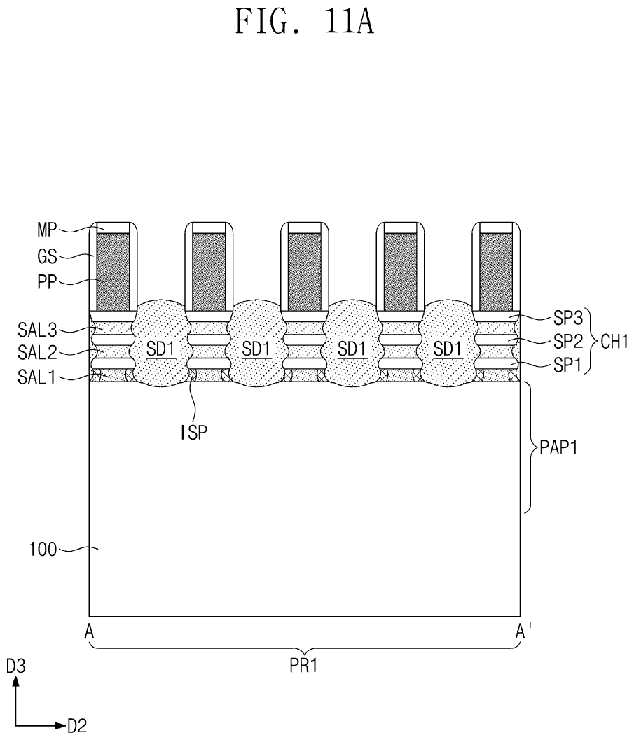

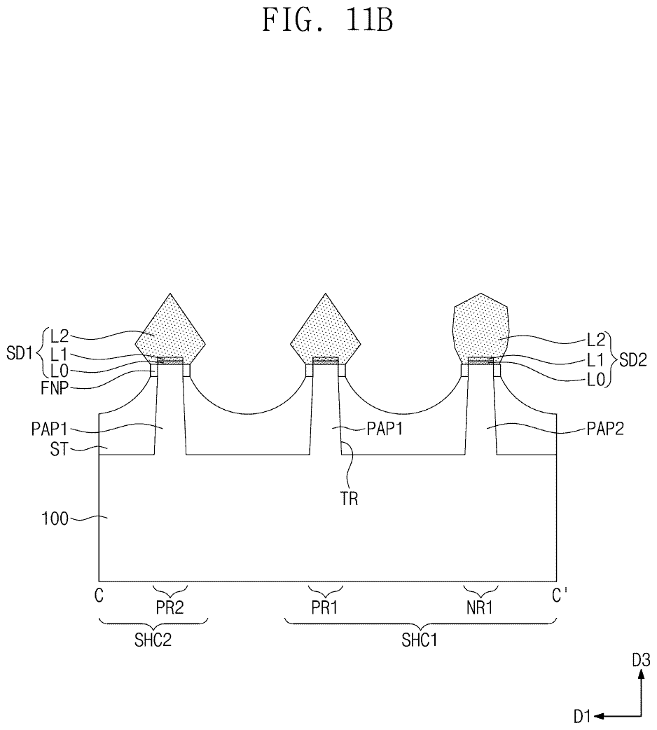

Referring to FIGS. 11A and 11B, the first source/drain patterns SD1 may be respectively formed in the first recesses RS1. The second source/drain patterns SD2 may be respectively formed in the second recesses RS2. The inner spacer ISP may be formed between the first source/drain pattern SD1 or the second source/drain pattern SD2 and the first sacrificial layer SAL1 among the second semiconductor layers. A method for forming the first source/drain pattern SD1, the second source/drain pattern SD2, and the inner spacer ISP will be described later.

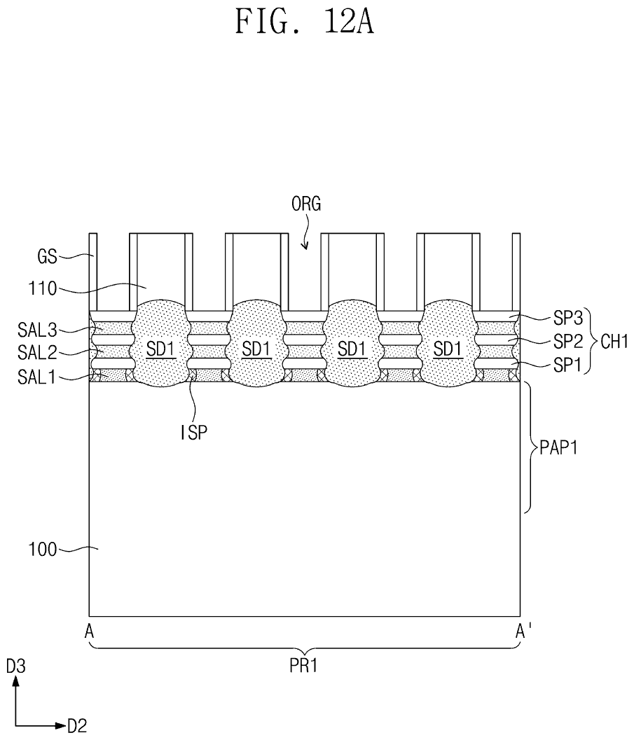

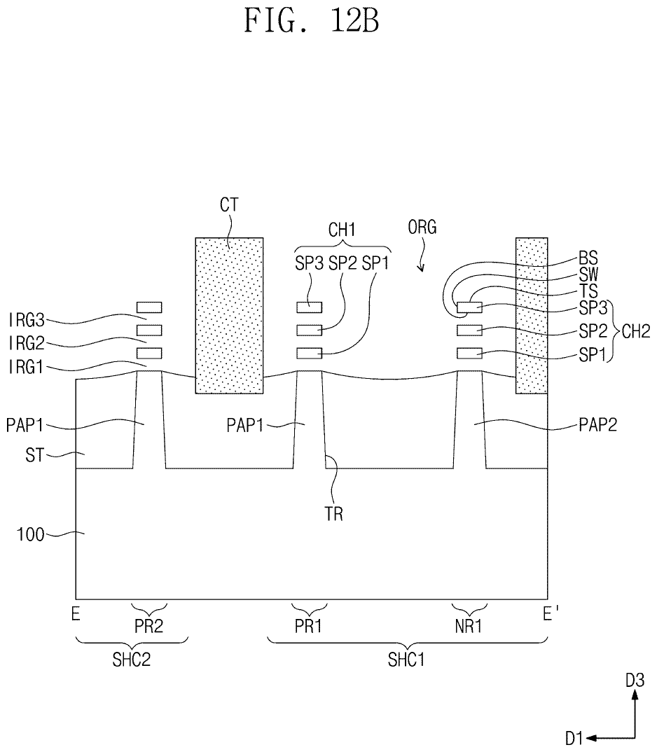

Referring to FIGS. 12A and 12B, the first interlayered insulating layer 110 covering the first source/drain pattern SD1, the second source/drain pattern SD2, the hard-mask patterns MP, and the gate spacers GS may be formed. For example, the first interlayered insulating layer 110 may include a silicon oxide layer.

The first interlayered insulating layer 110 may be planarized until upper surfaces of the sacrificial patterns PP are exposed. The first interlayered insulating layer 110 may be planarized by using an etch-back process or a chemical mechanical polishing (CMP) process. The hard-mask patterns MP may be fully removed during the planarization process. As a result, an upper surface of the first interlayered insulating layer 110 may be coplanar with the upper surfaces of the sacrificial patterns PP and the upper surfaces of the gate spacers GS.

One region of the sacrificial pattern PP may be selectively opened by using a photolithography process. For example, a region, of the sacrificial pattern PP, on the third boundary BD3 and the fourth boundary BD4 of the first single height cell SHC1 may be selectively opened. The opened region of the sacrificial pattern PP may be removed by selectively etching. The gate cutting pattern CT may be formed by filling the region in which the sacrificial pattern PP is removed with an insulating material (see FIG. 12B).

The exposed sacrificial patterns PP may be selectively removed. An outer region ORG exposing the first channel pattern CH1 and the second channel pattern CH2 may be formed by removing the sacrificial patterns PP. Removing the sacrificial patterns PP may include a wet etching process in which etchant selectively etching polysilicon is used.

Inner regions (e.g., First to third inner regions IRG1, IRG2, and IRG3) may be formed by selectively removing the second semiconductor layers (e.g., the first sacrificial layer SAL1, the second sacrificial layer SAL2, and the third sacrificial layer SAL3) exposed through the outer region ORG. Specifically, only the second semiconductor layers (e.g., the first sacrificial layer SAL1, the second sacrificial layer SAL2, and the third sacrificial layer SAL3) may be removed in a state in which the first to third semiconductor patterns SP1, SP2, and SP3 remain by performing an etching process of selectively etching the second semiconductor layers (e.g., the first sacrificial layer SAL1, the second sacrificial layer SAL2, and the third sacrificial layer SAL3). The etching process may have a high etch-rate with respect to silicon-germanium having a relatively high germanium concentration. For example, the etching process may have a high etch-rate with respect to silicon-germanium having a germanium concentration higher than about 10 at %.

During the etching process, the second semiconductor layers SAL (e.g., the first sacrificial layer SAL1, the second sacrificial layer SAL2, and the third sacrificial layer SAL3) on the first PMOSFET region PR1 and the second PMOSFET region PR2 and the first NMOSFET region NR1 and the second NMOSFET region NR2 may be completely removed. The etching process may be wet etching. An etching material used in the etching process may rapidly remove the second semiconductor layer SAL having a relatively high germanium concentration.

Only the stacked first to third semiconductor patterns SP1, SP2, and SP3 may remain on each of the first active pattern PAP1 and the second active pattern PAP2 by selectively removing the second semiconductor layers SAL (e.g., the first sacrificial layer SAL1, the second sacrificial layer SAL2, and the third sacrificial layer SAL3). First to third inner regions IRG1, IRG2, and IRG3 may be respectively formed through regions in which the second semiconductor layers SAL (e.g., the first sacrificial layer SAL1, the second sacrificial layer SAL2, and the third sacrificial layer SAL3) are removed. Specifically, a first inner region IRG1 may be formed between the first active pattern PAP1 or the second active pattern PAP2 and the first semiconductor pattern SP1, a second inner region IRG2 may be formed between the first semiconductor pattern SP1 and the second semiconductor pattern SP2, and a third inner region IRG3 may be formed between the second semiconductor pattern SP2 and the third semiconductor pattern SP3.

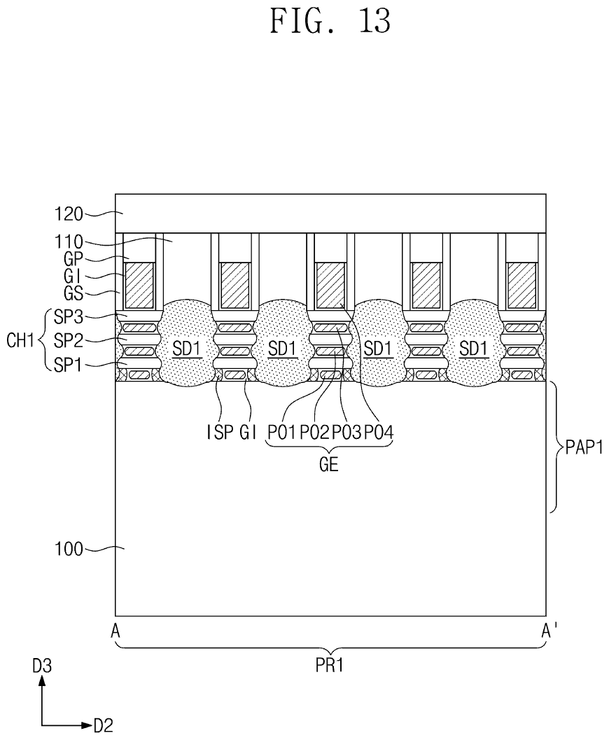

Referring to FIG. 13, the gate insulating layer GI may be conformally formed on the exposed first to third semiconductor patterns SP1, SP2, and SP3. The gate insulating layer GI may be formed so as to surround each of the first to third semiconductor patterns SP1, SP2, and SP3. The gate insulating layer GI may be formed in each of the first to third inner regions IRG1, IRG2, and IRG3. The gate insulating layer GI may be formed in the outer region ORG.

Referring to FIGS. 14A to 14D, the gate electrode GE may be formed on the gate insulating layer GI. The gate electrode GE may include the first to third inner parts PO1, PO2, and PO3 respectively formed in the first to third inner regions IRG1, IRG2, and IRG3, and the outer part PO4 formed in the outer region ORG. The gate electrode GE may be recessed to reduce a height thereof. The gate capping pattern GP may be formed on the recessed gate electrode GE.

The second interlayered insulating layer 120 may be formed on the first interlayered insulating layer 110. The second interlayered insulating layer 120 may include a silicon oxide layer. The active contact AC penetrating the second interlayered insulating layer 120 and the first interlayered insulating layer 110 to be electrically connected to at least one from among the first source/drain pattern SD1 and the second first source/drain pattern SD2 may be formed. The gate contact GC penetrating the second interlayered insulating layer 120 and the gate capping pattern GP to be electrically connected to the gate electrode GE may be formed.

Forming each of the active contact AC and the gate contact GC may include forming the barrier pattern BM and forming the conductive pattern FM on the barrier pattern BM. The barrier pattern BM may be conformally formed, and may include a metal layer/metal nitride layer. The conductive pattern FM may include a low resistance (e.g., a low electrical resistance) metal.

The separation structures DB may be respectively formed on the first boundary BD1 and the second boundary BD2 of the single height cell SHC. The separation structure DB may penetrate the gate electrode GE to extend from the second interlayered insulating layer 120 to the inside of the first active pattern PAP1 or the second active pattern PAP2. The separation structure DB may include an insulating material such as a silicon oxide layer or a silicon nitride layer.

Referring back to FIGS. 4, and 5A to 5E, the third interlayered insulating layer 130 may be formed on the active contacts AC and the gate contacts GC. The first metal layer M1 may be formed in the third interlayered insulating layer 130. The first metal layer M1 may include the first wire M1_I electrically connected to at least one from among the active contacts AC and the gate contacts GC. The fourth interlayered insulating layer 140 may be formed on the third interlayered insulating layer 130. The second metal layer M2 may be formed in the fourth interlayered insulating layer 140.

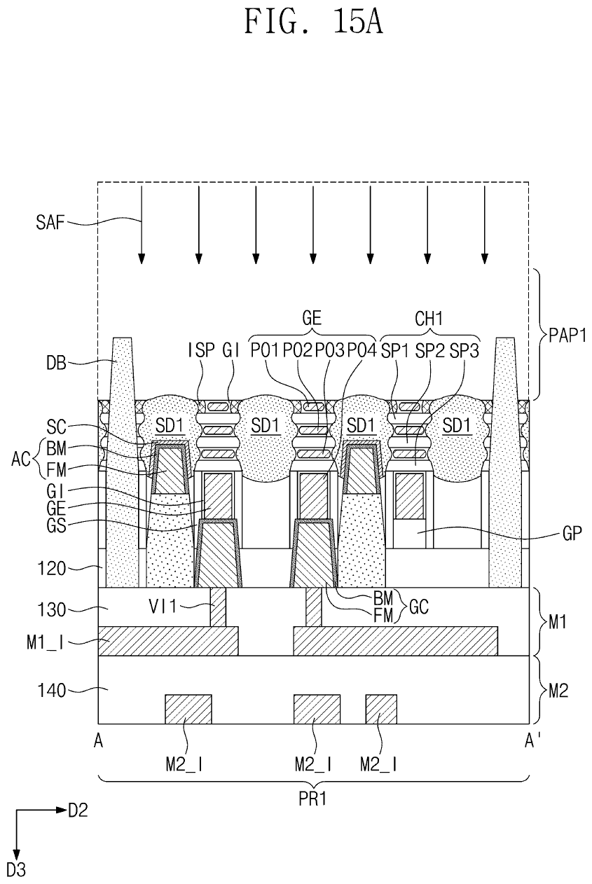

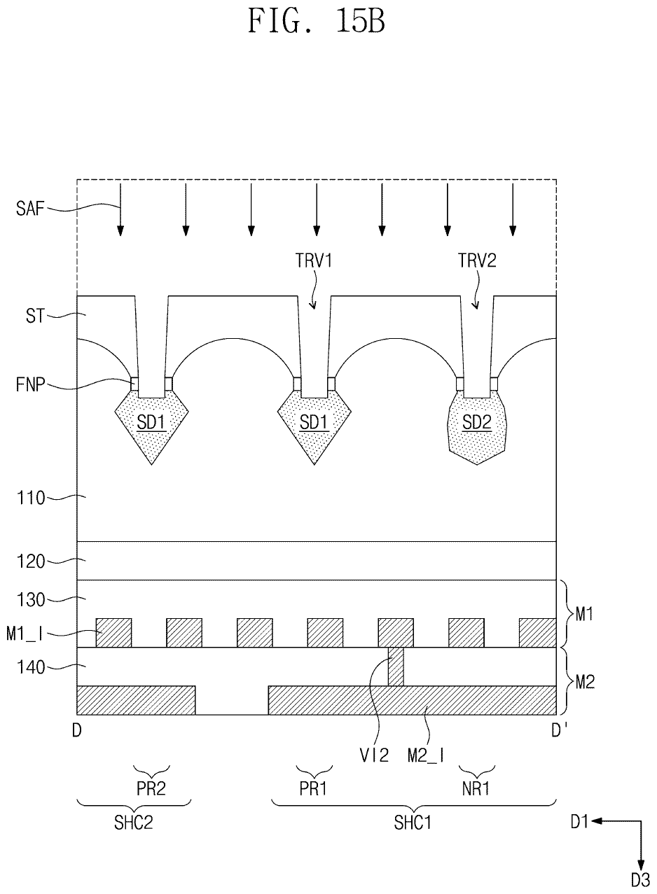

Referring to FIGS. 15A and 15B, after a back end of line (BEOL) process is completed, a bottom surface of the semiconductor substrate 100 may be exposed by turning the semiconductor substrate 100 over. The exposed semiconductor substrate 100 may be completely removed.

According to an embodiment of the present disclosure, removing the semiconductor substrate 100 may include reducing a thickness of the semiconductor substrate 100 by performing a planarization process SAF on a bottom surface of the semiconductor substrate 100, and performing a cleaning process of selectively removing silicon (Si) on the semiconductor substrate 100.

A first backside trench TRV1 may be formed in a region in which the first active pattern PAP1 is present by removing the semiconductor substrate 100. A second backside trench TRV2 may be formed in a region in which the second active pattern PAP2 is present by removing the semiconductor substrate 100 (see FIG. 14B).

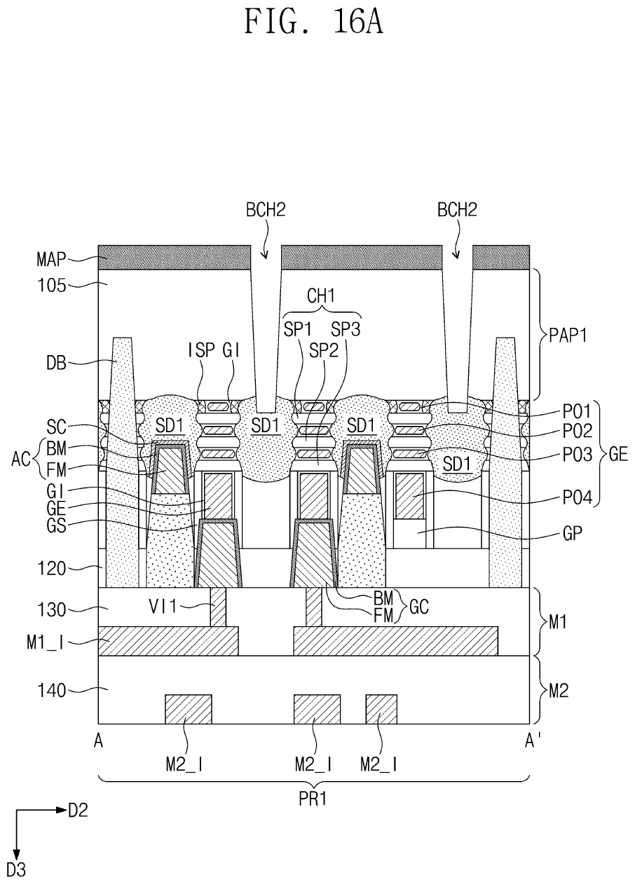

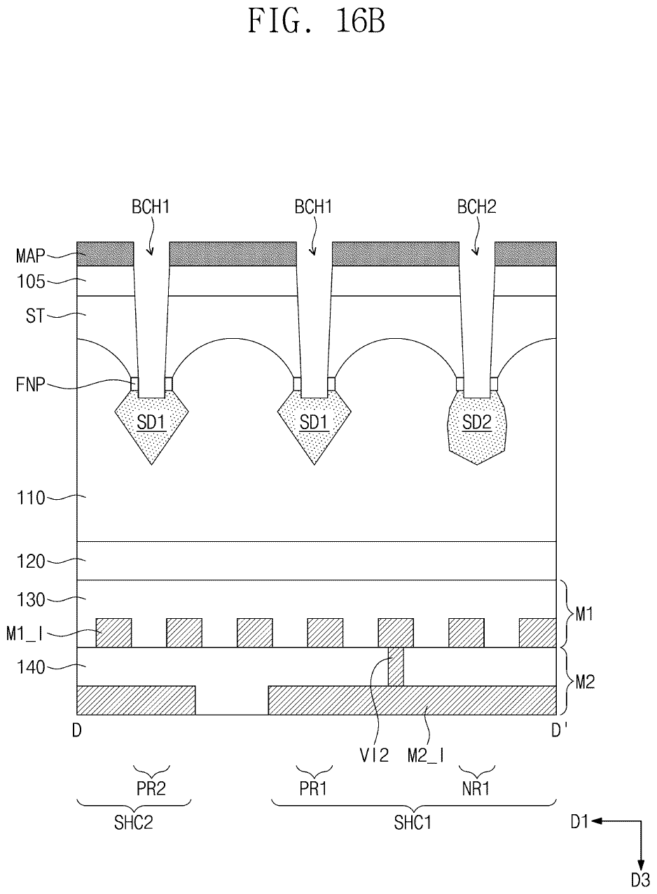

Referring to FIGS. 16A and 16B, the substrate 105 may be formed by filling a region in which the semiconductor substrate 100 is removed with an insulating material. The substrate 105 may include a silicon-based insulating layer. The substrate 105 may include the first insulating pattern AP1 that fills the first backside trench TRV1. The substrate 105 may include the second insulating pattern AP2 that fills the second backside trench TRV2.

A mask pattern MAP may be formed on the substrate 105. The mask pattern MAP may be formed through a photolithography process. A first backside contact hole BCH1 and a second backside contact hole BCH2 may be formed by performing an anisotropic etching process on the substrate 105 using the mask pattern MAP as an etching mask. The first backside contact hole BCH1 may expose the first source/drain pattern SD1. The second backside contact hole BCH2 may expose the second source/drain pattern SD2.

Referring back to FIGS. 5A to 5E, the mask pattern MAP may be selectively removed. The backside contacts BSC may be formed by filling the first backside contact hole BCH1 and the second backside contact hole BCH2 with metal.

The first through third lower power wires VPR1, VPR2, and VPR3 may be formed on the substrate 105. The first through third lower power wires VPR1, VPR2, and VPR3 may be connected to at least one from among the first backside contact BSC1 and the second backside contact BSC2. The power transmission network layer PDN may be formed on the first through third lower power wires VPR1, VPR2, and VPR3. The power transmission network layer PDN may be formed so as to apply a source voltage or a drain voltage to the first through third lower power wires VPR1, VPR2, and VPR3.

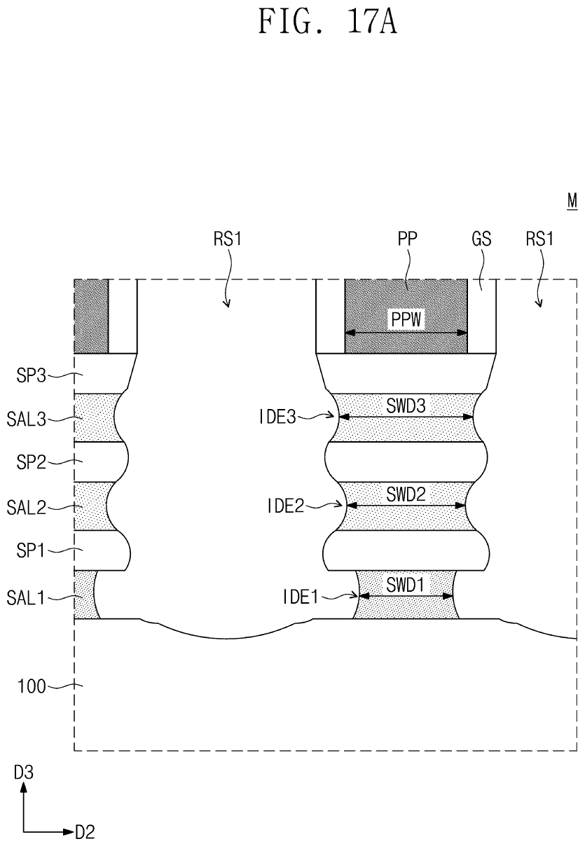

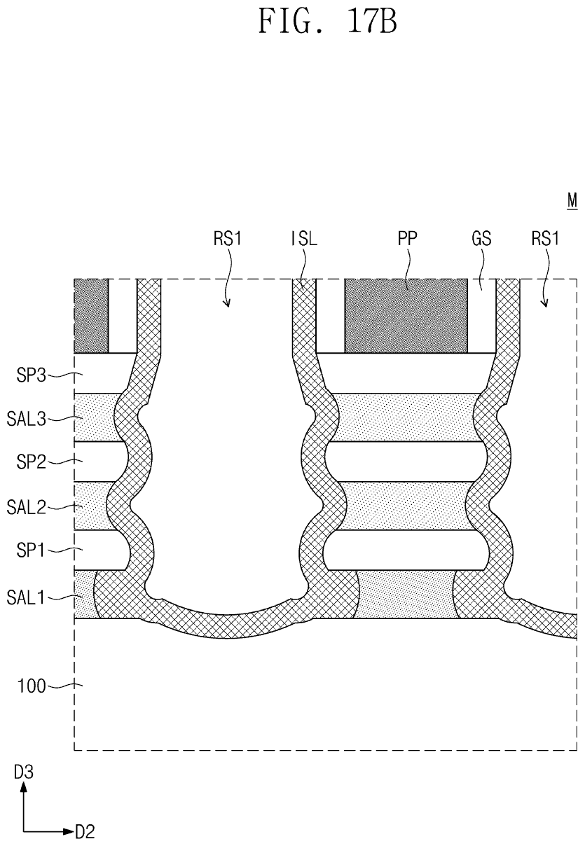

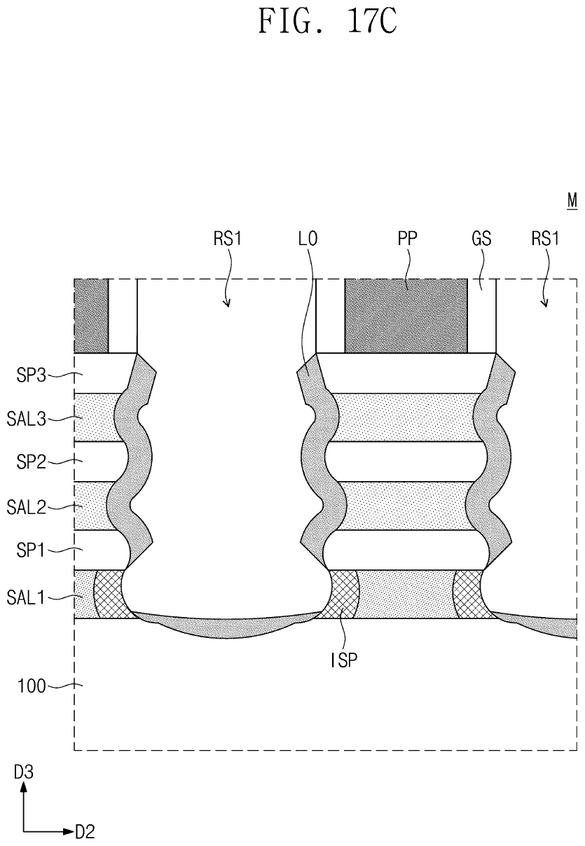

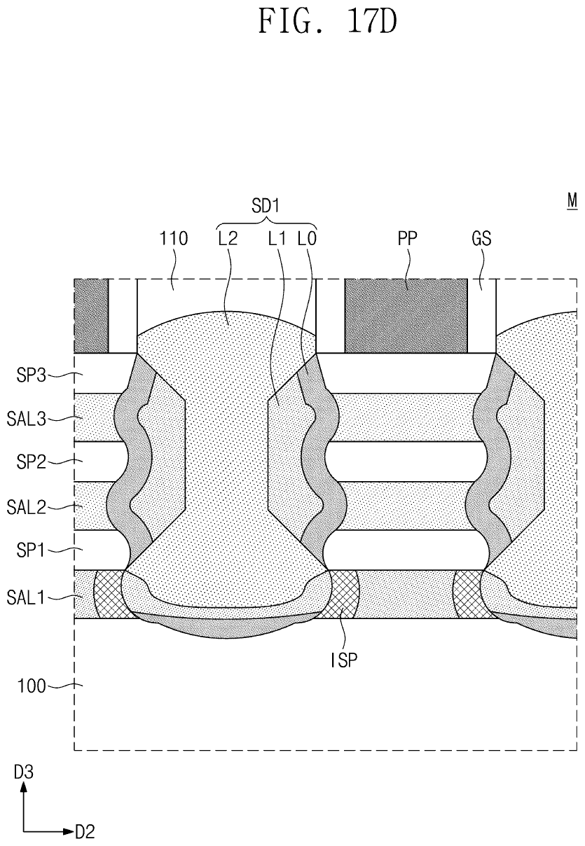

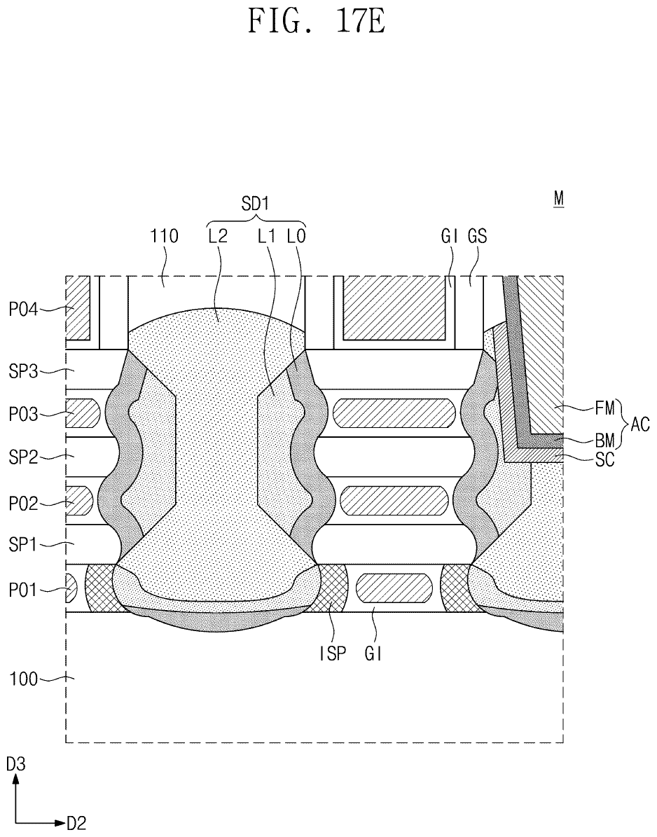

FIGS. 17A to 17E are enlarged diagrams for describing a method for manufacturing a semiconductor device according to the embodiment shown in FIG. 6. A method for forming the first source/drain pattern SD1, second source/drain pattern SD2, and the inner spacer ISP will be described with reference to FIGS. 17A to 17E in more detail. Descriptions with reference to FIGS. 17A to 17E may be also identically substantially applied to the second source/drain patterns SD2.

Referring to FIG. 17A, a plurality of indent regions may be formed in the first recesses RS1 according to FIGS. 10A to 10B. Specifically, the first to third sacrificial layers SAL1, SAL2 and SAL3 exposed by the first recesses RS1 may be indented in an etching process to form the indent regions. For example, the first sacrificial layer SAL1 may be indented to form a first indent region IDE1. The second sacrificial layer SAL2 may be indented to form a second indent region IDE2. The third sacrificial layer SAL3 may be indented to form a third indent region IDE3.

The first sacrificial layer SAL1 may be etched more than the second sacrificial layer SAL2 and the third sacrificial layer SAL3. The first sacrificial layer SAL1 may be indented more than the second sacrificial layer SAL2 and the third sacrificial layer SAL3. The first indent region IDE1 may have a larger volume than a volume of the second indent region IDE2 and a volume of the third indent region IDE3. This is because the first sacrificial layer SAL1 includes germanium (Ge) at a higher concentration than the second sacrificial layer SAL2 and the third sacrificial layer SAL3. In other words, this is because the first sacrificial layer SAL1 includes a material having etching selectivity different from those of the second sacrificial layer SAL2 and the third sacrificial layer SAL3.

Accordingly, after the etching process, a width SWD1 of the first sacrificial layer SAL1 may be smaller than a width SWD2 of the second sacrificial layer SAL2 and a width SWD3 of the third sacrificial layer SAL3. The width SWD1 of the first sacrificial layer SAL1 may be the same as or smaller than a width PPW of the sacrificial patterns PP. The width SWD2 of the second sacrificial layer SAL2 and the width SWD3 of the third sacrificial layer SAL3 may be greater than the width PPW of the sacrificial patterns PP.

Referring to FIG. 17B, an inner spacer layer ISL may be conformally formed in the first recess RS1. The inner spacer layer ISL may cover an upper surface of the semiconductor substrate 100 and sidewalls of the first to third semiconductor patterns SP1, SP2, and SP3. The inner spacer layer ISL may fill the first to third indent regions IDE1 to IDE3. The inner spacer layer ISL may cover the sidewalls of the first to third sacrificial layers SAL1, SAL2 and SAL3.

The inner spacer layer ISL may include an insulating material. For example, the inner spacer layer ISL may include at least one from among SiN, SiCN, SiON, SiBCN and SiOCN. In another example, the inner spacer layer ISL may include a multi-layer composed of at least two from among SiN, SiCN, SiON, SiBCN and SiOCN. In another example, the inner spacer layer ISL may include a Si-containing insulating material.

Referring to FIG. 17C, the inner spacer ISP may be formed by performing an etching process on the inner spacer layer ISL. All portions of the inner spacer layer ISL except for a portion thereof in the first indent region IDE1, may be removed in in the etching process. The first sacrificial layer SAL1 may not be exposed by the first recess RS1 due to the inner spacer ISP.

After the inner spacer ISP is formed, the first layer L0 may be formed by performing a selective epitaxial growth (SEG) process using an inner sidewall of the first recess RS1 as a seed layer. Specifically, the first layer L0 may be formed on the basis of the first to third semiconductor patterns SP1, SP2, and SP3, the second sacrificial layer SAL2, the third sacrificial layer SAL3, and the semiconductor substrate 100. The first layer L0 may not be formed on the basis of the inner spacer ISP. This is because since the SEG process is a process in which an epitaxial layer is grown on the basis of a crystal structure, the first layer L0 may not be grown on the inner spacer ISP including an insulating material. The SEG process may include a chemical vapor deposition (CVD) process or a molecular beam epitaxy (MBE) process.

The first layer L0 may be formed on the upper surface of the semiconductor substrate 100. The first layer L0 may be formed on sidewalls of the first to third semiconductor patterns SP1, SP2, and SP3 and sidewalls of the second sacrificial layer SAL2 and the third sacrificial layer SAL3. Since the inner spacer ISP is not formed on the sidewalls of the second sacrificial layer SAL2 and the third sacrificial layer SAL3, the first layer L0 may be formed well without a void and a crack.

The first layer L0 may include a semiconductor element (e.g., SiGe) having a greater lattice parameter than a lattice parameter of a semiconductor element of the semiconductor substrate 100. The first layer L0 may contain germanium (Ge) at a relatively low concentration. According to another embodiment of the present disclosure, the first layer L0 may contain only silicon (Si) without germanium (Ge). The first layer L0 may have a germanium (Ge) concentration of 0 at % to about 20 at %, but an embodiment of the present disclosure is not limited thereto.

Referring to FIG. 17D, the second layer L1 may be formed on the first layer L0. Specifically, the second layer L1 may be formed by performing a selective epitaxial growth (SEG) process using the first layer L0 as a seed layer. Accordingly, the second layer L1 may be in partial contact with the inner spacer ISP. The second layer L1 may contain germanium (Ge) at a higher concentration than the first layer L0. The second layer L1 may have a germanium (Ge) concentration of about 15 at % to about 40 at %, but an embodiment of the present disclosure is not limited thereto.

The third layer L2 may be formed on the second layer L1. Specifically, the third layer L2 may be formed by performing a selective epitaxial growth (SEG) process using the second layer L1 as a seed layer. The third layer L2 may be formed so as to completely or almost fill the first recess RS1. The third layer L2 may be in partial contact with the inner spacer ISP. The third layer L2 may contain germanium (Ge) at a higher concentration than the first layer L0 and the second layer L1. The third layer L2 may have a germanium (Ge) concentration of about 30 at % to about 70 at %, but an embodiment of the present disclosure is not limited thereto.

During forming the first to third layers L0, L1 and L2, an impurity (e.g., boron, gallium, or indium) that makes the first source/drain pattern SD1 have a P-type may be in-situ injected. In another example, after the first source/drain pattern SD1 is formed, the impurity may be injected into the first source/drain pattern SD1.

In another example, an impurity (e.g., phosphorous, arsenic or antimony) that makes the second source/drain pattern SD2 have an N-type may be in-situ injected. In another example, after the second source/drain pattern SD2 is formed, the impurity may be injected into the second source/drain pattern SD2.

Referring to FIG. 17E, the first to third sacrificial layers SAL1, SAL2 and SAL3 may be respectively replaced with the first to third inner parts PO1, PO2, and PO3 of the gate electrode GE, and the sacrificial pattern PP may be replaced with the outer part PO4 of the gate electrode GE. This may be substantially the same as what is described with reference to FIGS. 12A to 13.

Referring back to FIG. 6, the semiconductor substrate 100 may be replaced with the substrate 105. Thereafter, the backside contact BSC extending into the first source/drain pattern SD1 may be formed. The backside contact BSC may be connected to the third layer L2 of the first source/drain pattern SD1.

According to the manufacturing method according to an embodiment of the present disclosure, the inner spacer ISP may be formed only in the first indent region IDE1. Accordingly, an electric short and leakage current may be prevented by increasing a distance between the backside contact BSC and the first inner part PO1. The first layer L0 of the first source/drain pattern SD1 and second source/drain pattern SD2 may be formed well without a void and a crack by omitting the inner spacer ISP in the second indent region IDE2 and the third indent region IDE3.

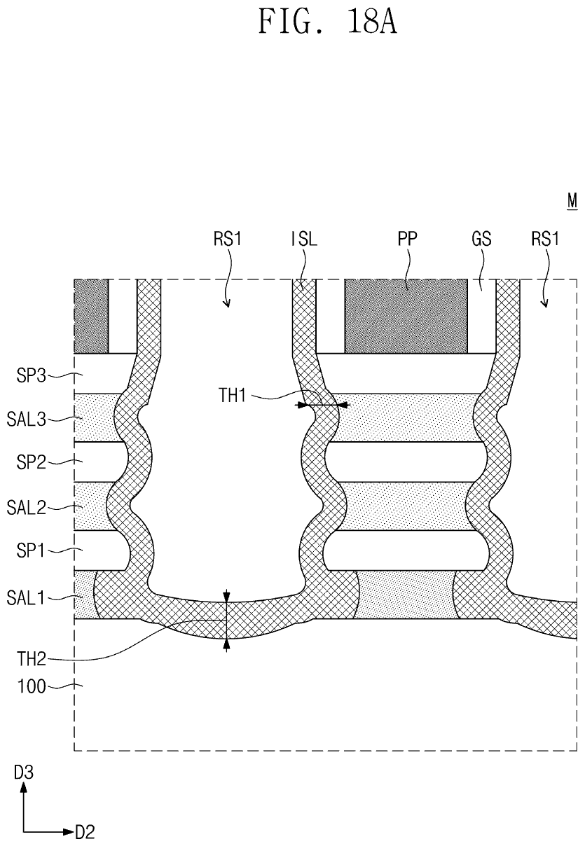

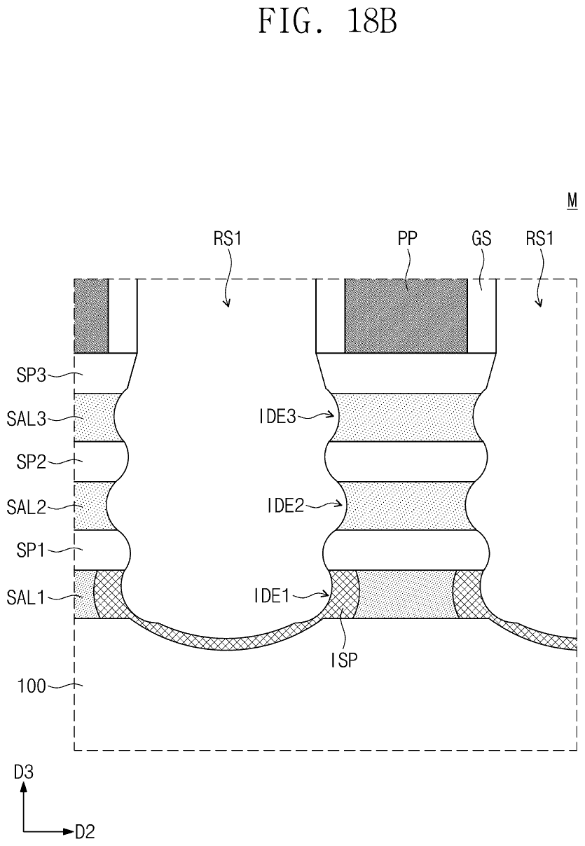

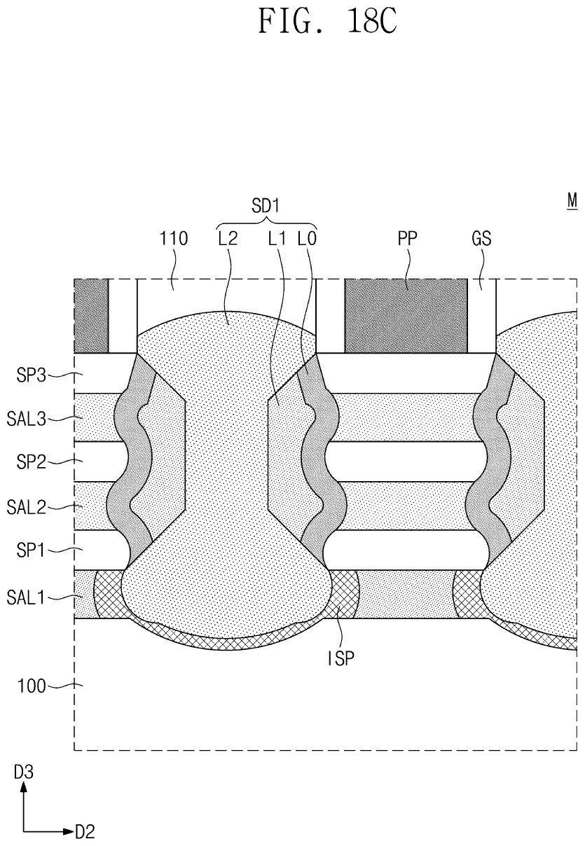

FIGS. 18A to 18C are enlarged diagrams for describing a method for manufacturing a semiconductor device according to an embodiment of FIG. 7. Detailed duplicate descriptions for technological features made with reference to FIGS. 17A to 17E may be omitted. Descriptions with reference to FIGS. 18A to 18C may be also substantially identically applied to the second source/drain patterns SD2.

Referring to FIG. 18A, the inner spacer layer ISL may be conformally formed in the first recess RS1. The inner spacer layer ISL may cover the upper surface of the semiconductor substrate 100 and an inner sidewall of the first recess RS1. The inner spacer layer ISL may not be uniform. Specifically, a portion of the inner spacer layer ISL covering the sidewalls of the first to third semiconductor patterns SP1, SP2, and SP3 and/or the second sacrificial layer SAL2 and the third sacrificial layer SAL3 may have a first thickness TH1. A portion of the inner spacer layer ISL covering the upper surface of the semiconductor substrate 100 may have a second thickness TH2. The second thickness TH2 may be greater than the first thickness TH1.

Referring to FIG. 18B, the inner spacer ISP may be formed by performing an etching process on the inner spacer layer ISL. Since the portion of the inner spacer layer ISL covering the upper surface of the semiconductor substrate 100 is relatively thick, the inner spacer layer ISL may remain on the upper surface of the semiconductor substrate 100 after the etching process. The semiconductor substrate 100 may not be exposed by the first recess RS1 due to the remaining portions of the inner spacer ISP.

Referring to FIG. 18C, the first layer L0, the second layer L1, and the third layer L2 may be sequentially formed in the first recess RS1. The third layer L2 may be formed so as to fill all of a lower portion of the first recess RS1. This is because since the semiconductor substrate 100 is not exposed by the inner spacer ISP, an SEG process is not performed on the basis of the semiconductor substrate 100. Accordingly, the third layer L2 of FIG. 18C may have a larger volume than a volume of the third layer L2 of FIG. 17E.

Referring back to FIG. 7, the semiconductor substrate 100 may be replaced with the substrate 105. Thereafter, the backside contact BSC extending into the first source/drain pattern SD1 may be formed. The backside contact BSC may penetrate the inner spacer ISP to be connected to the third layer L2 of the first source/drain pattern SD1.

In a three-dimensional field effect transistor according to an embodiment of the present disclosure, an inner spacer may be interposed only between a source/drain pattern and a lowermost portion of a gate electrode. Accordingly, a distance between a backside contact connected to the source/drain pattern and the gate electrode may be increased, and thus an electric short occurring therebetween may be prevented.

In addition, the inner spacer may be omitted between remaining parts of the gate electrode except for the lowermost portion thereof and the source/drain pattern. Accordingly, when an SEG process is performed, a first layer of the source/drain pattern may be formed without a void or a crack. As a result, reliability and electrical characteristics of a semiconductor device according to an embodiment of the present disclosure may be improved.

Although non-limiting example embodiments of the present disclosure have been described above with reference to the accompanying drawings, it is understood that the present disclosure is not limited to these example embodiments, and that various changes and modifications can be made by one ordinary skilled in the art within the spirit and scope of the present disclosure. Therefore, it should be understood that the example embodiments described above are non-limiting examples in all respects.

What is claimed is:

1. A semiconductor device comprising:
a substrate;
an active pattern on the substrate;
a source/drain pattern on the active pattern;
a channel pattern connected to the source/drain pattern, the channel pattern comprising semiconductor patterns that are spaced apart from each other; and
a gate electrode extending in a first direction such as to cross the channel pattern,
wherein the semiconductor patterns comprise a first semiconductor pattern, a second semiconductor pattern on the first semiconductor pattern, and a third semiconductor pattern on the second semiconductor pattern,
wherein the gate electrode comprises:
a first inner part between the active pattern and the first semiconductor pattern;
a second inner part between the first semiconductor pattern and the second semiconductor pattern; and
a third inner part between the second semiconductor pattern and the third semiconductor pattern, and
wherein a width of the first inner part is a smaller than a width of the second inner part and a width of the third inner part.

2. The semiconductor device of claim 1, wherein the gate electrode further comprises an outer part on the third semiconductor pattern, and
wherein the width of the first inner part is equal to or smaller than a width of the outer part.

3. The semiconductor device of claim 1, wherein the gate electrode further comprises an outer part on the third semiconductor pattern, and
a minimum width of the second inner part and a minimum width of the third inner part are the same as or greater than a width of the outer part.

4. The semiconductor device of claim 1, further comprising:
a lower power wire in a lower portion of the substrate;
a backside contact penetrating the active pattern, the source/drain pattern being electrically connected to the lower power wire by the backside contact; and
an inner spacer between the backside contact and the first inner part.

5. The semiconductor device of claim 4, wherein the inner spacer extends under a bottom surface of the source/drain pattern, and
an extension part of the inner spacer is in contact with the backside contact.

6. The semiconductor device of claim 4, further comprising a power transmission network layer under the substrate,
wherein the substrate is an insulating substrate, and
wherein the power transmission network layer is configured to apply a source voltage or a drain voltage to the lower power wire.

7. The semiconductor device of claim 1, further comprising an inner spacer between the first inner part and the source/drain pattern.

8. The semiconductor device of claim 7, wherein the source/drain pattern comprises:
a first part in contact with the inner spacer;
a second part protruding toward the second inner part; and
a third part protruding toward the third inner part, and
wherein the first part has a higher germanium (Ge) concentration than a germanium concentration of the second part and a germanium (Ge) concentration of the third part.

9. The semiconductor device of claim 1, wherein the source/drain pattern comprises a first layer in contact with the semiconductor patterns, a second layer on the first layer, and a third layer on the second layer,
wherein the third layer has a higher germanium (Ge) concentration than a germanium (Ge) concentration of the second layer,
wherein the second layer has a higher germanium (Ge) concentration than a germanium (Ge) concentration of the first layer, and
wherein a width of an upper portion of the third layer in a second direction that crosses the first direction decreases in a third direction towards a central portion of the third layer, wherein the third direction crosses the first direction and the second direction.

10. The semiconductor device of claim 9, wherein a width of a lower portion of the third layer in the second direction increases in a fourth direction away from the central portion of the third layer, wherein the fourth direction is opposite to the third direction.

11. The semiconductor device of claim 9, further comprising:
a lower power wire in a lower portion of the substrate; and
a backside contact penetrating the active pattern,
wherein a lower portion of the third layer is connected to the backside contact.

12. The semiconductor device of claim 9, wherein the first layer and the second layer are between the substrate and the third layer,
wherein the semiconductor device further comprises an inner spacer between the first inner part and the source/drain pattern,
wherein at least a portion of the second layer is in contact with the inner spacer.

13. A semiconductor device comprising:
a substrate;
an active pattern on the substrate;
a source/drain pattern on the active pattern;
a channel pattern connected to the source/drain pattern, the channel pattern comprising semiconductor patterns spaced apart from each other, wherein the semiconductor patterns comprises a first semiconductor pattern that is a lowermost semiconductor pattern among the semiconductor patterns;
a gate electrode extending in a first direction such as to cross the channel pattern; and
an inner spacer between the substrate and the first semiconductor pattern,
wherein the source/drain pattern comprises:
a first part in contact with the inner spacer; and
a second part in contact with one of the semiconductor patterns other than the first semiconductor pattern, and
wherein the first part has a higher germanium (Ge) concentration than a (Ge) concentration of the second part.

14. The semiconductor device of claim 13, wherein the gate electrode comprises a first inner part between the substrate and the first semiconductor pattern,
wherein the semiconductor device further comprises:
a lower power wire in a lower portion of the substrate; and
a backside contact penetrating the active pattern, the source/drain pattern being electrically connected to the lower power wire by the backside contact,
wherein the inner spacer is between the backside contact and the first inner part.

15. The semiconductor device of claim 13, wherein the source/drain pattern comprises a first layer in contact with the semiconductor patterns, a second layer on the first layer, and a third layer on the second layer,
the third layer has a higher germanium (Ge) concentration than a germanium (Ge) concentration of the second layer,
the second layer has a higher germanium (Ge) concentration than a germanium (Ge) concentration of the first layer, and
a width of an upper portion of the third layer in a second direction that crosses the first direction decreases in a third direction toward a central portion of the third layer, wherein the third direction crosses the first direction and the second direction.

16. The semiconductor device of claim 15, wherein a width of a lower portion of the third layer in the second direction increases in a fourth direction away from the central portion of the third layer, wherein the fourth direction is opposite to the third direction.

17. A semiconductor device comprising:
an insulating substrate;
a channel pattern on the insulating substrate, the channel pattern comprising a first semiconductor pattern, a second semiconductor pattern on the first semiconductor pattern, and a third semiconductor pattern on the second semiconductor pattern, wherein the first semiconductor pattern, the second semiconductor pattern, and the third semiconductor pattern are spaced apart from each other;
a source/drain pattern connected to the channel pattern;
a gate electrode extending in a first direction such as to cross the channel pattern, the gate electrode comprising:
a first inner part between the insulating substrate and the first semiconductor pattern;
a second inner part between the first semiconductor pattern and the second semiconductor pattern;
a third inner part between the second semiconductor pattern and the third semiconductor pattern; and
an outer part on the third semiconductor pattern;
a gate insulating layer between the gate electrode and the channel pattern;
a gate spacer on a sidewall of the gate electrode;
a gate capping pattern on an upper surface of the gate electrode;
an interlayered insulating layer on the source/drain pattern and the gate capping pattern;
a gate contact penetrating the interlayered insulating layer and the gate capping pattern, the gate contact electrically connected to the gate electrode;
a first metal layer on the interlayered insulating layer, and the first metal layer comprising a first wire electrically connected to the gate contact;
a lower power wire in a lower portion of the insulating substrate;
a power transmission network layer under the insulating substrate; and
a backside contact penetrating the insulating substrate, the backside contact electrically connected the lower power wire and the source/drain pattern,
wherein a width of the first inner part is the same as or a smaller than a width of the outer part, and
a minimum width of the second inner part and a minimum width of the third inner part are greater than a width of the outer part.

18. The semiconductor device of claim 17, further comprising an inner spacer between the source/drain pattern and the first inner part,
wherein the inner spacer is not between the source/drain pattern and the second inner part, and not between the source/drain pattern and the third inner part.

19. The semiconductor device of claim 18, wherein the inner spacer extends under a bottom surface of the source/drain pattern, and
an extension part of the inner spacer is in contact with the backside contact.

20. The semiconductor device of claim 18, wherein the source/drain pattern comprises:
a first layer in contact with the second semiconductor pattern and the third semiconductor pattern;
a second layer on the first layer; and
a third layer on the second layer,
wherein the third layer has a higher germanium (Ge) concentration than a germanium (Ge) concentration of the second layer,
wherein the second layer has a higher germanium (Ge) concentration than a germanium (Ge) concentration of the first layer,
wherein the second layer is between the third layer of the source/drain pattern and the substrate, and
wherein at least a portion of the second layer is in contact with the inner spacer.
